(19) United States
(12) Patent Application Publication
(10) Pub. No.: US 2025/0287697 A1
(43) Pub. Date: Sep. 11, 2025

(54) POWER SEMICONDUCTOR WAFER OF HIGH-FREQUENCY BRIDGE ARM INTEGRATED WITH SINGLE CRYSTAL WAFER, AND POWER CONVERSION MODULE

(71) Applicant: SHANGHAI METAPWR ELECTRONICS CO., LTD, Shanghai (CN)

(72) Inventors: Jianhong ZENG, Shanghai (CN); Shouyu HONG, Shanghai (CN); Xiaoni Xin, Shanghai (CN)

(73) Assignee: SHANGHAI METAPWR ELECTRONICS CO., LTD, Shanghai (CN)

(21) Appl. No.: 19/073,033

(22) Filed: Mar. 7, 2025

(30) Foreign Application Priority Data
Mar. 7, 2024 (CN) 202410258032.5

(51) Int. Cl. H10D 89/10; H01L 23/528; H01L 25/18; H10D 1/60

(52) U.S. Cl. CPC H10D 89/10; H01L 23/5286; H01L 25/18; H10D 1/60

(57) ABSTRACT

The application discloses a power semiconductor wafer of a high-frequency bridge arm integrated with a single crystal wafer. The power semiconductor wafer comprises a substrate and a device structure area, wherein the device structure area comprises a first switch area, a second switch area and a logic circuit area; a DC+ electrode, a DC− electrode and an SW electrode are arranged on the power semiconductor wafer; and the first switch area and the second switch area comprise long-strip-shaped areas parallel to the long edge and are arranged in parallel. Another aspect of the present application further provides a power conversion module, comprising a bridge arm circuit, wherein the bridge arm circuit comprises an outer decoupling capacitor and a power semiconductor wafer, or comprises an outer decoupling capacitor, a laminated decoupling capacitor and a power semiconductor wafer.

### CROSS-REFERENCE TO RELATED APPLICATIONS

This application claims the priority benefit of Chinese patent application CN 202410258032.5 filed on Mar. 7, 2024. The entirety of each of the above-mentioned patent applications is hereby incorporated by reference herein and made a part of this specification.

### BACKGROUND

With the progress of the semiconductor process, the working voltage of the transistor is lower and lower, so that the working voltage of the computing power chip such as a CPU, a GPU, a TPU, an NPU and the like (hereinafter referred to as XPU) is lower and lower, the working current corresponding to the XPU with the same power becomes larger and larger, for example, the working current exceeds 1000 amperes, and the working voltage is lower than 1V. Therefore, in order to accurately control the low voltage under the large current, the power converter (i.e., the VRM module) is also higher and higher in working frequency.

Therefore, the key component DrMOS (also referred to as SPS, Switch Power Supply) of the VRM module needs to complete high-current conversion at high frequency.

The circuit of the VRM module is generally a BUCK circuit, as shown in FIG. 1A. The BUCK circuit comprises an input decoupling capacitor Cbus, an upper switch QH, a lower switch QL, an inductor L and an output capacitor Co. The QH and QL form a (high frequency) bridge arm circuit. The working frequency is f, and the input voltage Vin is converted into an output voltage Vo to supply power to the XPU.

An input loop comprises the input decoupling capacitor Cbus, the upper switch QH and the lower switch QL. Since the upper switch QH and the lower switch QL work in high-frequency, a voltage overshoot can be formed on the input loop inductor Lloop under high frequency due to V=Lloop*di/dt, so that the efficiency, reliability and electromagnetic interference are influenced. Therefore, the input loop inductance Lloop determines the performance of the VRM module at a high frequency. The smaller the inductance Lloop of the input loop, the higher the working frequency can be.

In order to make the input loop inductance Lloop as small as possible, the DrMOS increasingly adopts a monolithic process, that is, the high-frequency bridge arm circuit is integrated in a single wafer, so that the distance between the upper switch QH and the lower switch QL is reduced as much as possible, and the input loop inductance Lloop is reduced. The single crystal wafer contains QH, QL, and a logical circuit area Logical composed of a driver, even current sampling, temperature sampling, and the like.

According to the traditional single crystal wafer scheme layout, as shown in FIG. 1B, the lower switch QL, the upper switch QH and the logic circuit area Logical respectively occupy one area, the areas are arranged in parallel, the input decoupling capacitor Cbus is arranged on the edge corresponding to the arrangement direction so as to be electrically connected with the upper switch QH and the lower switch QL respectively, and the method is very simple and practical. However, since the lower switch QL and the upper switch QH are respectively concentrated in a corresponding area, the area is larger than the area of a single switch structure unit, the area of an input loop comprising the input decoupling capacitor Cbus, the lower switch QL and the upper switch QH is large, the frequency is limited and is difficult to be higher than 1 MHz. According to the improvement scheme of the prior art, as shown in FIG. 1C, the area occupied by QL and the area occupied by QH are broken down into smaller parts, for example, the area occupied by QL and the area occupied by QH are divided into three smaller areas (for the purpose of conveniently showing high-frequency bridge arm grouping, the central axis of a part of small areas is shown in FIG. 1C, the area marked as QH adjacent in FIG. 1C is an integral area, and the adjacent area marked as QL is also an integral area.) so that the area of the input loop including the switches in every two adjacent areas is greatly reduced, the circuit in the area is further reduced in parallel, the application frequency is greatly improved, and the working frequency can be easily increased to 1 MHz or even more than 3 MHz. However, according to the scheme, the wafer is divided into a plurality of areas on the wafer, so that the high and low voltage boundary lines on the chip are numerous, and the wafer utilization rate is low. On the other hand, as shown in FIG. 1D, in actual use, in order to reduce the loop area to be as small as possible, the input decoupling capacitor Cbus is placed on the two sides of the DrMOS wafer, the actual equivalent loop inductance can be as low as 100 pH or even below; and compared with 500 pH of a scheme corresponding to a traditional scheme in FIG. 1B, the frequency characteristic can be increased by multiple times, so that the circuit is particularly suitable for high-frequency work above 2 MHz. However, due to the fact that the input decoupling capacitor Cbus is arranged on the outer side of the wafer along the direction of the partition arrangement, that is, the direction is perpendicular to the area boundary lines corresponding to the upper switch QH and the lower switch QL; therefore, the area of the input loop including the upper switch QH, the lower switch QL and the input decoupling capacitor Cbus which are next to each other is smaller, the area of the input loop including the corresponding device away from the edge is larger; that is, the distance between each high-frequency bridge arm circuit and the input decoupling capacitor Cbus is inconsistent, so that the input loop inductances with different values are achieved; the current distribution is not uniform in the high-frequency switch process, the switching loss is influenced, the reliability problem can be caused if different areas of the wafer cannot work synchronously, but the reliability of the DrMOS is the most important. If the current of each high-frequency bridge arm circuit is as uniform as possible, the width of the short edge of the wafer is reduced, so that the aspect ratio of the wafer becomes larger when the same power area is maintained, and the yield is influenced.

Therefore, how to improve the structure of the wafer, how to reduce the inductance of the input loop, how to improve the current sharing performance and reliability under the high-frequency working condition and optimize the aspect ratio of the wafer under the condition of the same power area size is an urgent problem to be solved.

### SUMMARY

In view of the above, one of the objectives of the application is to provide a power semiconductor wafer of a single crystal wafer integrated high-frequency bridge arm comprises a substrate and a device structure area, wherein the device structure area is arranged on one surface of the substrate; the device structure area comprises a first switch area, a second switch area and a logic circuit area; the logic circuit area provides driving signals to the first switch and the second switch;

wherein the first switch area is used for arranging a first switch, the second switch area is used for arranging a second switch, and the first switch and the second switch are connected in series to form a high-frequency bridge arm; a DC+ electrode, a DC− electrode and an SW electrode are arranged on the power semiconductor wafer, the DC+ electrode and the DC− electrode are electrically connected with the two ends of the high-frequency bridge arm respectively, and the SW electrode is electrically connected with the midpoint end of the high-frequency bridge arm;

wherein the device structure area is provided with a long edge and a short edge, the length of the long edge is greater than the length of the short edge; at least one part of the first switch area is a first long-strip-shaped area parallel to the long edge, at least one part of the second switch area is a second long-strip-shaped area parallel to the long edge, and the first long-strip-shaped area and the second long-strip-shaped area are arranged side by side in the direction perpendicular to the long edge.

Preferably, wherein the device structure area is a long-strip-shaped area, the device structure area only comprises a first long-strip-shaped area and a second long-strip-shaped area, and the first long-strip-shaped area and the second long-strip-shaped area are adjacent and are arranged in parallel.

Preferably, wherein the logic circuit area is arranged in the area adjacent to the short edge or to the long edge of the power semiconductor area.

Preferably, at least one long edge is used for setting a decoupling capacitor, the decoupling capacitor is arranged along the long edge, the decoupling capacitor is arranged on the outer side of the device structure area, and the decoupling capacitor is connected with the high-frequency bridge arm in parallel.

Preferably, wherein the second switch area surrounds at least three sides of the first switch area.

Preferably, wherein the second switch area completely surrounds the first switch area.

Preferably, wherein the logic circuit area is disposed at a central axis of the device structure area parallel to the long edge.

Preferably, wherein the second switch area is C-shaped, the first switch area is a sleeping T shape, the second switch area partially surrounds the first switch area, and the first switch area and the second switch area are complementary.

Preferably, wherein the first switch area and the second switch area are both C-shaped; the C-shaped at the inner side at least partially surrounds the logic circuit area; and the C-shaped at the outer side surrounds at least three sides of the C shape at the inner side.

Preferably, wherein the logic circuit area is a sleeping T shape.

Preferably, wherein the first switch area is C-shaped, the second switch area fully surrounds the first switch area, the first switch area and the second switch area are combined to form a C-shaped power area, and the C-shaped power area surrounds at least three sides of the logic circuit area.

Preferably, wherein the first switch area is C-shaped; the second switch area partially surrounds the first switch area, and the first switch area and the second switch area are combined to form a C-shaped power area; a part of the left edge of the C-shaped power area is a first switch area; and the C-shaped power area surrounds at least three sides of the logic circuit area.

Preferably, wherein the logic circuit area comprises a third long-strip-shaped area parallel to the long edge, and the third long-strip-shaped area is arranged at the central axis of the device structure area parallel to the long edge.

Preferably, wherein the central axis penetrates through the logic circuit area.

Preferably, wherein the first switch area and the second switch area form a power area, and the power area surrounds at least three sides of the logic circuit area.

Preferably, wherein the power area surrounds all of the logic circuit areas.

Preferably, wherein the logic circuit area divides the device structure area into a first switch area group and a second switch area group, and the first switch area group and the second switch area group are respectively arranged on two opposite sides of the logic circuit area; and the first switch area group and the second switch area group are symmetrical along a central axis; and a first switch area and a second switch area are respectively arranged in the first switch area group and in the second switch area group.

Preferably, wherein the switch areas arranged on the two sides of the logic circuit area are long-strip-shaped, and the long sides of each long-strip-shaped are parallel to each other.

Preferably, wherein the device structure area further comprises a driving area, and the driving area is a long-strip-shaped parallel to the long edge; and the driving area is arranged in the logic area, and every two adjacent of the first switching area and the second switching area.

Preferably, wherein the switch areas arranged on the two sides of the logic circuit area are respectively provided with a long-strip-shaped switch area.

Preferably, wherein the second switch area surrounds at least three sides of the first switch area.

Preferably, wherein the second switch area completely surrounds the first switch area.

Preferably, wherein the second switch area is C-shaped, and the first switch area is long-strip-shaped; the first switch area is adjacent to the logic circuit area at one long edge, and the first switch area is adjacent to the second switch area at the other long edge and the two short edges.

Preferably, wherein the device structure area further comprises a driving area, and the driving area is a long strip parallel to the long edge; and each first switching area is adjacent to at least one driving area, and/or each second switching area is adjacent to at least one driving area.

Preferably, wherein the power semiconductor wafer is characterized in that a bus layer is arranged above the device structure area, the bus layer comprises a DC+ bus wiring layer, a DC− bus wiring layer and an SW bus wiring layer, and the DC+ electrode, the DC− electrode and the SW electrode are electrically connected with the high-frequency bridge arm through the corresponding bus wiring layer.

Preferably, wherein the SW bus wiring layer is disposed across the first switch area and the second switch area; the DC+ bus wiring layer is disposed on the first switch area and the DC− bus wiring layer is disposed on the second switch area, or the DC+ bus wiring layer is disposed on the second switch area, and the DC− bus wiring layer is disposed on the first switch area.

Preferably, the power semiconductor wafer, further comprising a DC+ bus lead-out piece, a DC− bus lead-out piece, and an SW bus lead-out piece. Each wiring area is provided with at least one bus lead-out piece; the bus lead-out piece is electrically connected to the corresponding wiring area; the total cross-sectional area of the SW bus lead-out piece is greater than the total cross-sectional area of the DC+ bus lead-out piece.

Preferably, wherein the device structure area comprises a first sub-area, and a second switch area in the first sub-area surrounds at least three sides of the first switch area; the first sub-area corresponds to a first bus layer, and a DC+ bus wiring layer in the first bus layer semi-surrounds the DC− bus wiring layer and the SW bus wiring layer.

Preferably, wherein the device structure area comprises a second sub-area, the first switch area and the second switch area in the second sub-area are both long-strip-shaped, and the first switch area is arranged between the second switch areas; the second sub-area corresponds to the second bus layer, the SW bus wiring layer of the second bus layer spans the second switch area, and the length of the SW bus wiring layer in the longitudinal direction is greater than 50% of the length of the second sub-area in the longitudinal direction; and the DC+ bus wiring layer of the second bus layer is arranged between the DC− bus wiring layer.

Preferably, the DC+ electrodes in two adjacent second bus layers are electrically connected, and DC− electrodes in two adjacent second bus layers are electrically connected.

Preferably, wherein the SW bus wiring layer comprises two extension sections, and the two extension sections are respectively arranged between the DC+ bus wiring layer and the two DC− bus wiring layers.

Preferably, wherein the device structure area comprises a second sub-area, the first switch area and the second switch area in the second sub-area are both long-strip-shaped, and the first switch area is arranged between the second switch areas; the second sub-area corresponds to the second bus layer, and the second bus layer is arranged in the longitudinal direction according to the sequence of the DC− bus wiring layer, the SW bus wiring layer, the DC+ bus wiring layer, the SW bus wiring layer and the DC− bus wiring layer; and each DC− bus wiring layer, the SW bus wiring layer and the DC+ bus wiring layer are each provided with a bus lead-out piece.

Preferably, wherein the device structure area comprises a second sub-area, the first switch area and the second switch area in the second sub-area are both long-strip-shaped, and the first switch area in the second sub-area is arranged between the second switch area and the logic circuit area; the second sub-area corresponds to the second bus layer, and the plane layout of the second bus layer is sequentially arranged in the longitudinal direction according to the sequence of the DC− bus wiring layer, the SW bus wiring layer and the DC+ bus wiring layer; and the DC− bus wiring layer, the SW bus wiring layer and the DC+ bus wiring layer are each provided with a bus lead-out piece.

Preferably, wherein the DC− bus wiring layer, the SW bus wiring layer and the DC+ bus wiring layer are all long-strip-shaped; and the bus lead-out piece is aligned and arranged in the longitudinal column direction.

Preferably, wherein the bus lead-out piece arranged on the SW bus wiring layer is staggered with the position of the bus lead-out piece arranged on the DC− bus wiring layer and the DC+ bus wiring layer; and the DC− bus wiring layer, the SW bus wiring layer and the DC+ bus wiring layer are respectively arranged to alternately change with wide and narrow along the transverse, and are wide at the position where the bus lead-out piece is arranged.

Preferably, wherein the device structure area comprises a first sub-area and a second sub-area, and the first switch area and the second switch area in the first sub-area are in an enclosed layout; and the first switch area and the second switch area in the second sub-area are arranged in parallel; and the first sub-area is located at the end of the second sub-area; and the DC− bus wiring layer, the SW bus wiring layer and the DC+ bus wiring layer in the second sub-area are repeatedly formed by multiple repeating units side by side; the DC− bus wiring layer in the first sub-area is connected with the DC− bus wiring layer in the second sub-area; the SW bus wiring layer in the first sub-area is connected with the SW bus wiring layer in the second sub-area; and the DC+ bus wiring layer in the first sub-area is connected with the DC+ bus wiring layer in the second sub-area.

Preferably, wherein the device structure area further comprises a built-in capacitor area;
the built-in capacitor area and the first switch area are adjacent in the long edge direction, and/or the built-in capacitor area and the second switch area are adjacent in the long edge direction;
the built-in capacitor area is used for setting a device area capacitor, and the device area capacitor and the high-frequency bridge arm are connected in parallel.

Preferably, wherein the device structure area is arranged on a plane layout layer by layer from inside to outside according to the sequence of a built-in capacitor area, a first switch area and a second switch area.

Preferably, wherein the device structure area is arranged on a plane layout layer by layer from inside to outside according to the sequence of the first switch area, the second switch area and the built-in capacitor area.

Preferably, at least two first switch areas and at least two second switch areas are arranged, and the device structure areas are sequentially arranged in the longitudinal direction according to the sequence of a second switch area, a first switch area, a built-in capacitor area, a first switch area and a second switch area on a plane layout.

The power semiconductor wafer of claim 37, at least two second switch areas are arranged, the device structure areas are arranged on a plane layout layer by layer from inside to outside according to the sequence of a second switch area, a built-in capacitor area, a first switch area and a second switch area.

Preferably, the power semiconductor wafer, further comprising a built-in layered capacitor, the built-in layered capacitor being formed by a dielectric layer embedded in the bus wiring layer, and the built-in layered capacitor and the high-frequency bridge arm being connected in parallel.

Preferably, wherein the bus wiring layer further comprises a capacitor connection pad, and the capacitor connection pad is located at a corresponding position of the logic circuit area projected on the bus wiring layer.

Preferably, wherein the capacitor connection pads are provided with a plurality of arrays arranged in an array.

Preferably, wherein the logic circuit area provides two groups of driving signals with 180 degrees of staggered phases to the first switch area group and the second switch area group.

Preferably, wherein the device structure area comprises a plurality of switch area groups with the same area, and each switch area group comprises at least one first switch area and at least one second switch area; and the logic circuit area is used for providing at least two groups of mutually staggered driving signals to the switch area group, and each group of driving signals respectively drives different switch area groups.

Preferably, the plurality of switch area groups are arranged along the central axis of the device structure area, and arranged the two sides of the central axis symmetrically.

Preferably, wherein the first switch area and the second switch area in each switch area group are b long-strip-shaped.

Preferably, wherein the plurality of switch area groups comprise first to fourth switch area groups, the first switch area group and the third switch area group are located on one side of the central axis of the device structure area, and the second switch area group and the fourth switch area group are located on the other side of the central axis of the device structure area; and the logic circuit area is used for providing four groups of driving signals with 90 degrees of staggered phases in sequence to the first to fourth switch area groups.

Preferably, wherein the logic circuit area is located on the central axis of the device structure area, and arranged the two sides of the logic circuit area symmetrically.

A power conversion module, comprising a bridge arm type circuit;
wherein the bridge arm type circuit comprises an outer decoupling capacitor and the power semiconductor wafer. The outer decoupling capacitor array is arranged on the outer side of at least one long edge of the power semiconductor wafer, and the outer decoupling capacitor and the high-frequency bridge arm are connected in parallel.

Preferably, wherein the bridge arm circuit further comprises a laminated decoupling capacitor; the laminated capacitor is stacked above the power semiconductor wafer and corresponds to the logic circuit area; the laminated decoupling capacitor and the high-frequency bridge arm are connected in parallel; and the laminated decoupling capacitor is a silicon capacitor.

Compared with the prior art, the application has the following beneficial effects:
According to the application, the first switch area, the second switch area or a part of the strip-shaped area of the first switch area and the second switch area are arranged in the direction parallel to the long edge, so that the total length of the boundary line of the first switch area and the second switch area is prolonged as much as possible, so that the maximum equivalent width of the input loop is reduced, the area of the input loop and the corresponding loop inductance are reduced, and the frequency performance of the wafer is improved;
The boundary line of the first switch area and the second switch area is parallel to the long edge of the wafer, and the arrangement direction of the long strip-shaped area is perpendicular to the long edge of the wafer, and perpendicular to the arrangement direction of the high-frequency bridge arm and the array direction of the input decoupling capacitor, so that the sizes of the input loops formed by different device structure units are close to the same, and the current sharing performance and reliability during high-frequency work are improved;
The synchronism of the switch device working by the hard switch is improved through the arrangement of the driving area adjacent to the switch area; the bus impedance is reduced by arranging the bus wiring layer formed by combining the plurality of sub-areas of the same structure;
According to the application, the multi-frequency-band multi-stage input loop decoupling is formed through the built-in and external decoupling capacitor combination, and the frequency performance of the wafer is further improved.

### BRIEF DESCRIPTION OF THE DRAWINGS

FIG. 1A to FIG. 1D are schematic structural diagrams of a power semiconductor wafer of a single-crystal wafer integrated high-frequency bridge arm in the prior art.

FIG. 2A to FIG. 2M are schematic structural diagrams according to Embodiment 1 of the present application.

FIG. 3A and FIG. 3B are schematic structural diagrams of Embodiment 2 of the present application.

FIG. 4A to FIG. 4H are schematic structural diagrams of Embodiment 3 of the present application.

FIG. 5A to FIG. 5C are schematic structural diagrams of Embodiment 4 of the present application.

FIG. 6A to FIG. 6F are schematic structural diagrams of Embodiment 5 of the present application.

FIG. 7 is a schematic structural diagram of Embodiment 6 of the present application.

### DESCRIPTION OF THE EMBODIMENTS

According to the technical scheme in the embodiment of the application, the technical scheme in the embodiment of the application is clearly and completely described below in combination with the drawings in the embodiment of the application, obviously, the described embodiments are only a part but not all of the embodiments of the present application on the basis of the embodiments of the present application, all other embodiments obtained by a person of ordinary skill in the art without creative efforts shall fall within the protection scope of the present application.

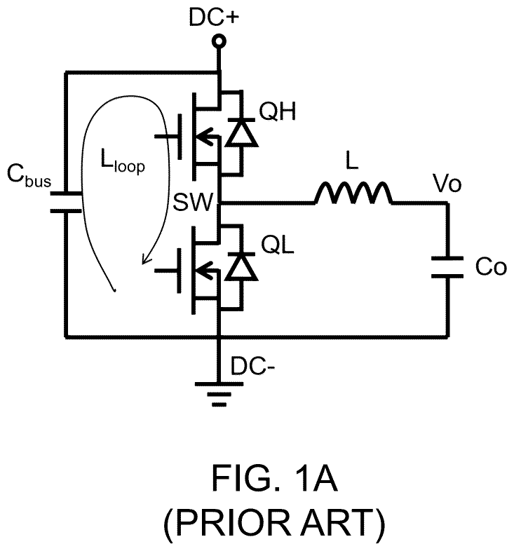

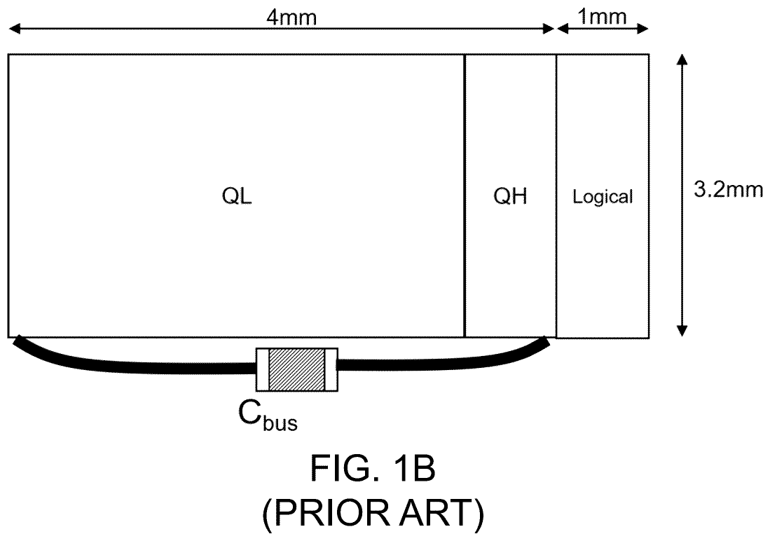

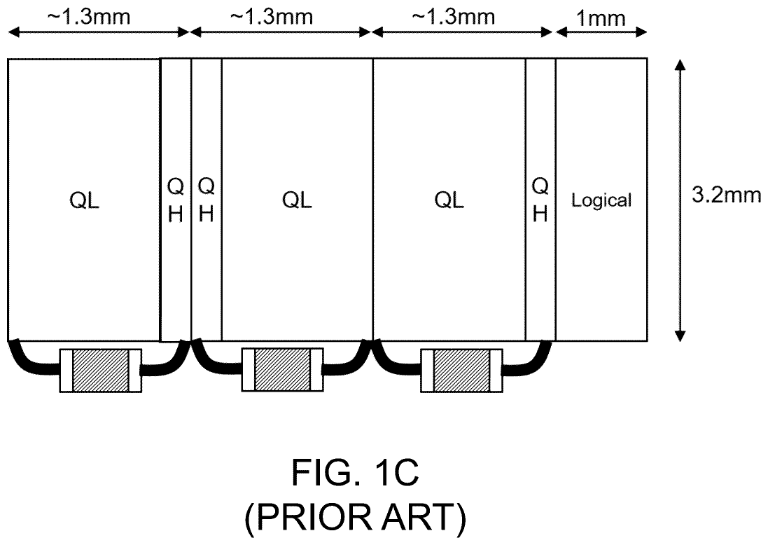

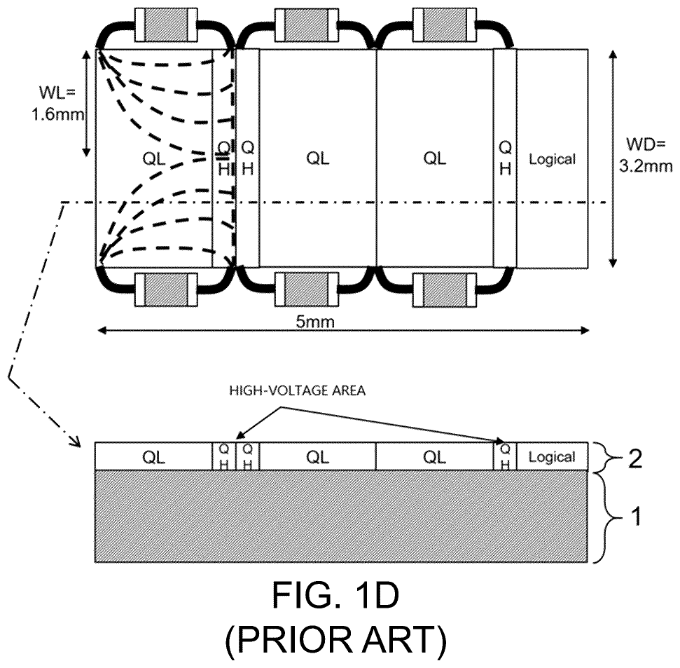

The wafer size specification of a common single-crystal wafer integrated DrMOS in the prior art is 3.2 mm*5 mm; in this size, the maximum equivalent width WL of the input loop on the wafer is half of the width of the short edge according to the scheme shown in FIG. 1D; that is, WL=0.5*3.2=1.6 mm; in order to better disclose the beneficial effects of the present application, the following embodiments are mainly described by using the specification or the specification of the same wafer area (16 mm²). The solution of the present application is not limited thereto, and can also be used for other size specifications.

### Embodiment 1

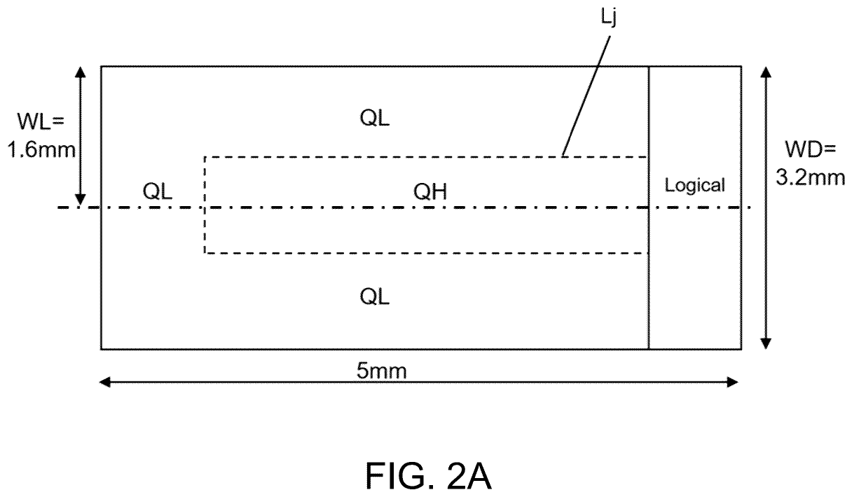

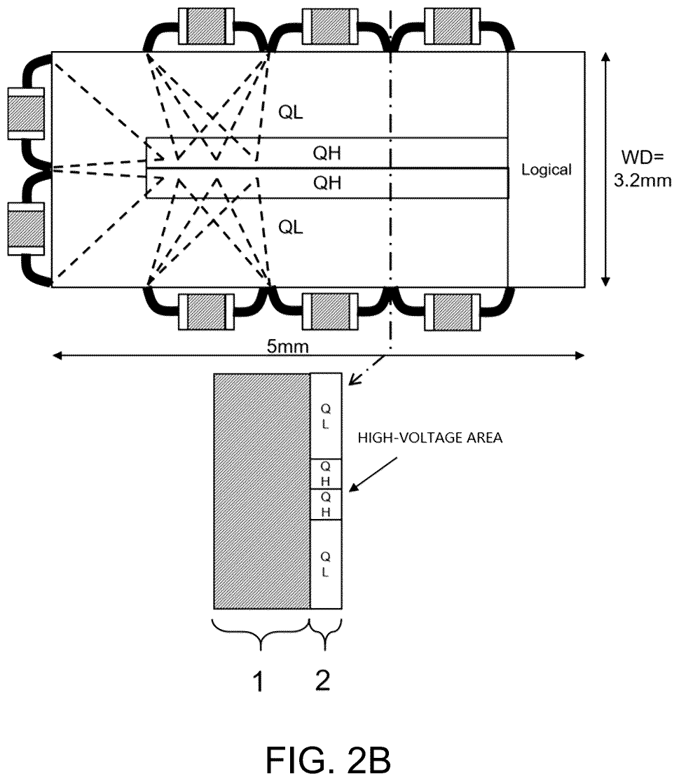

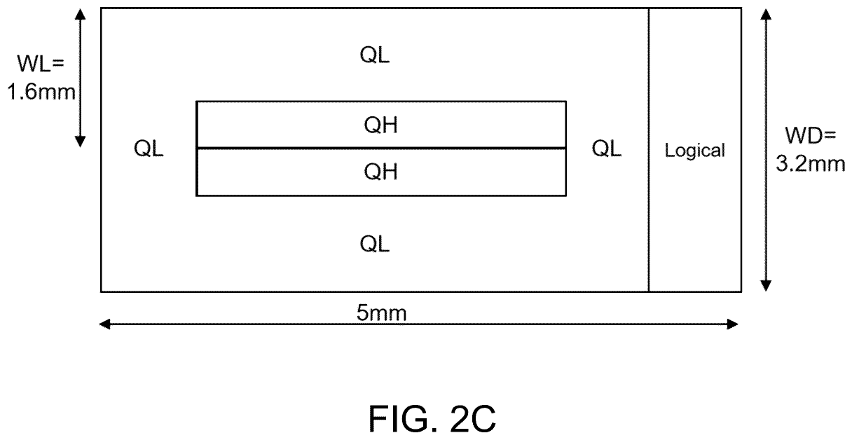

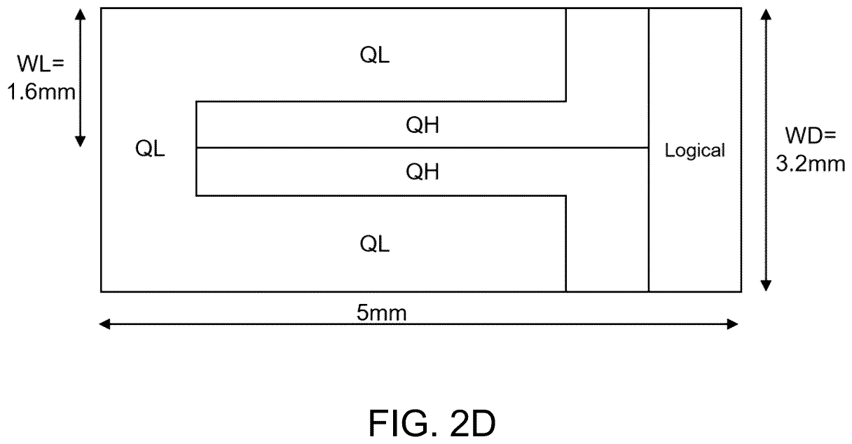

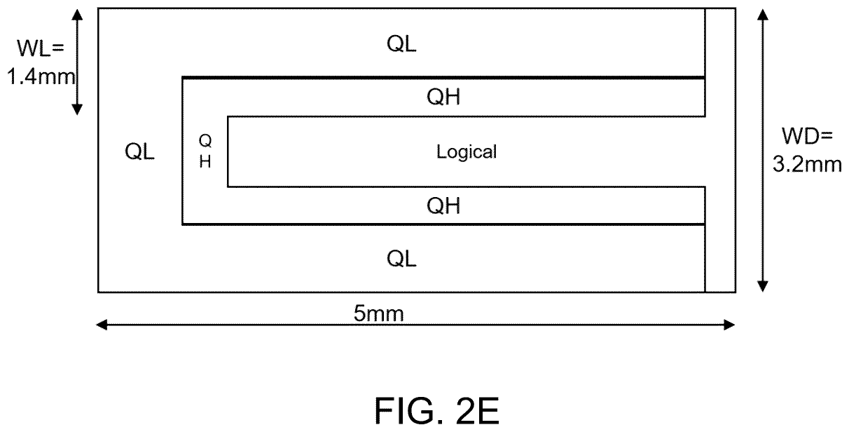

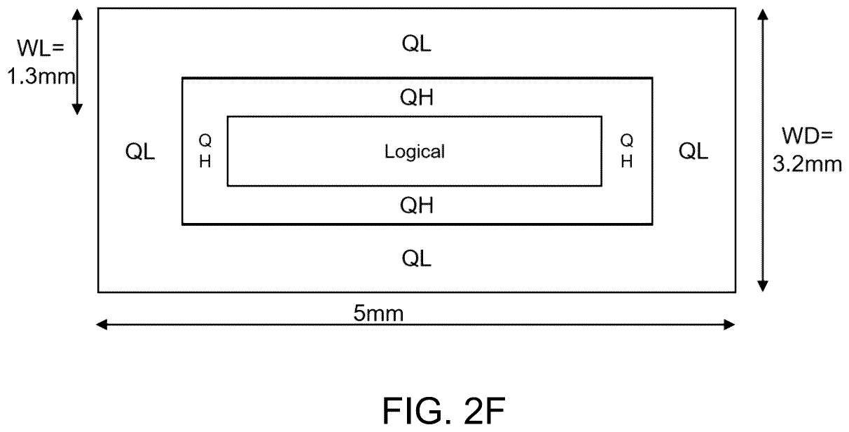

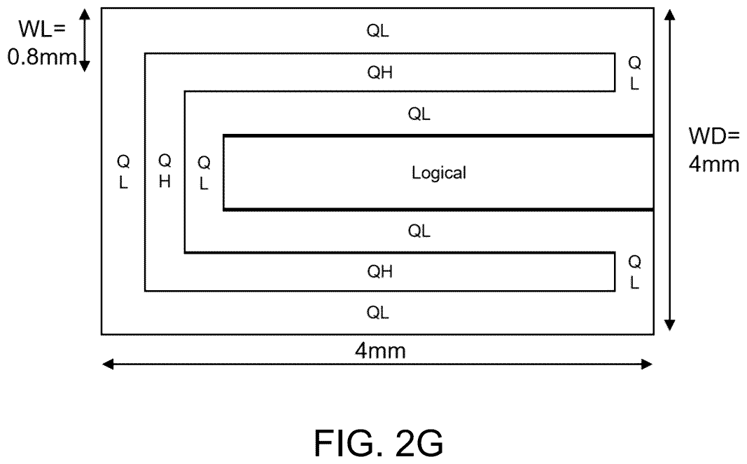

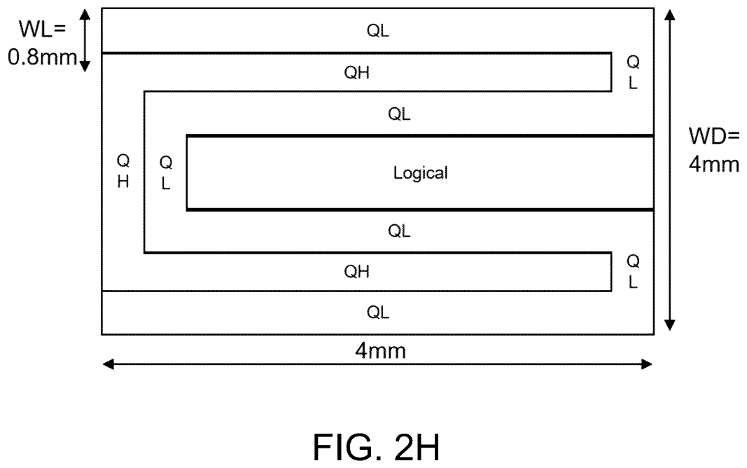

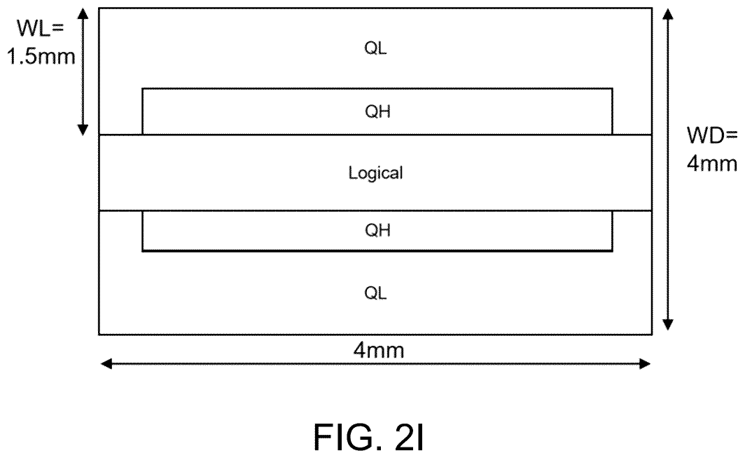

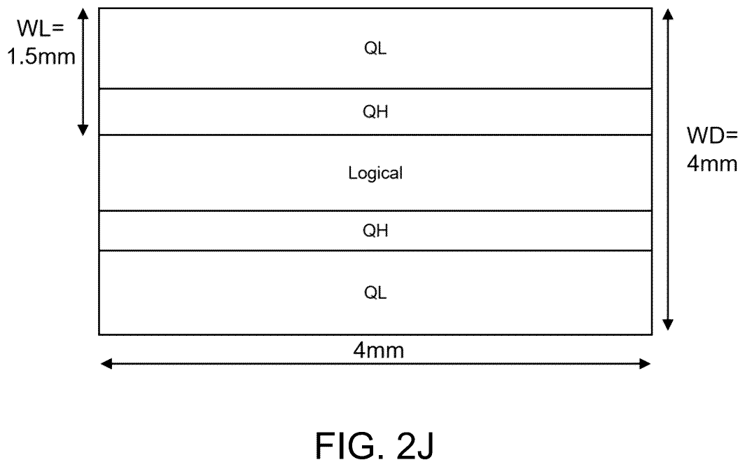

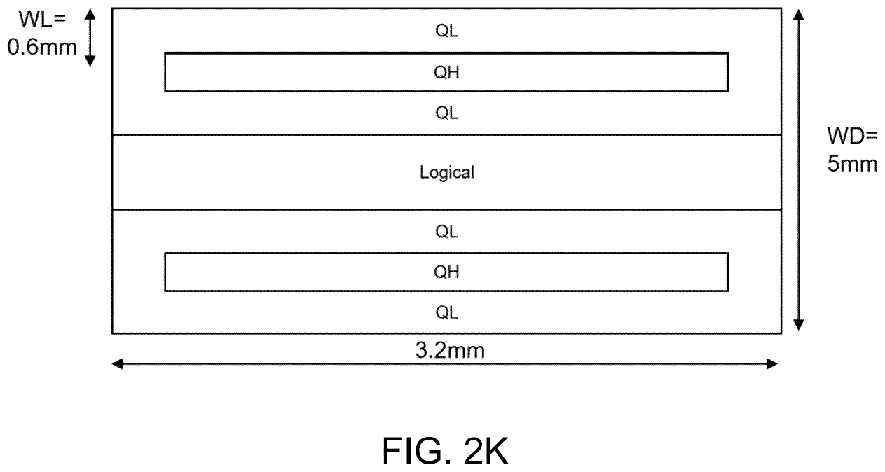

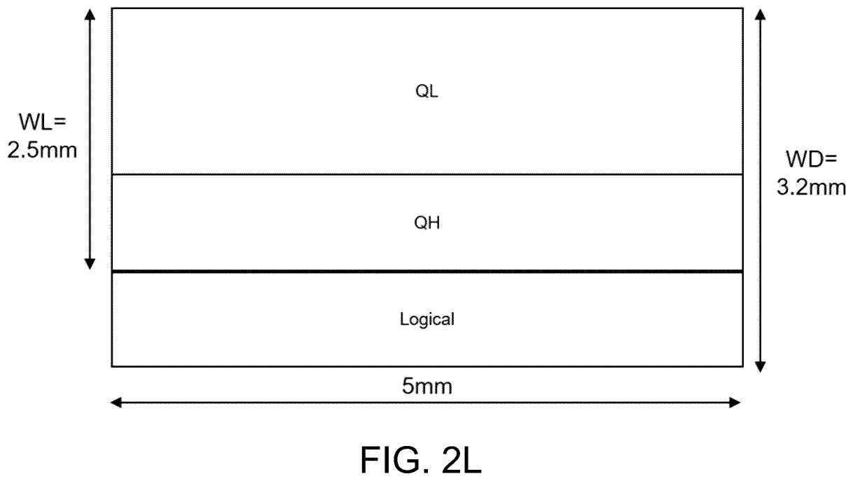

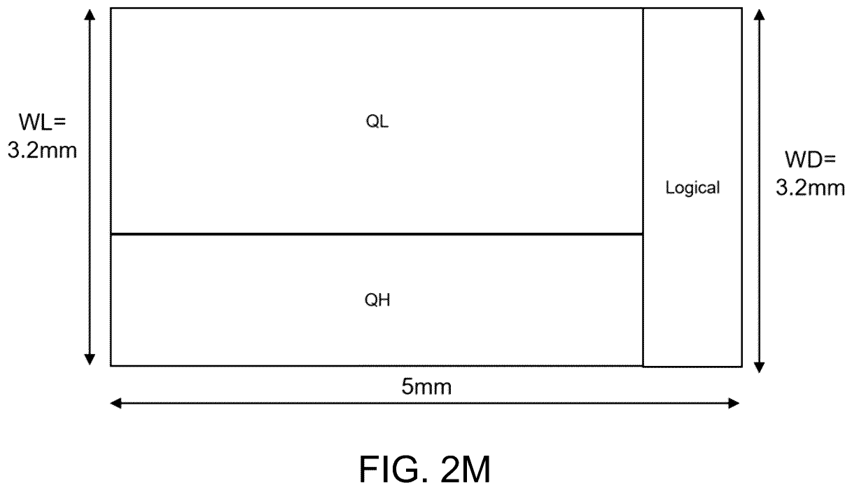

As shown in FIG. 2A and FIG. 2B, the power semiconductor wafer of the present embodiment comprises a substrate 1 and a device structure area 2, the device structure area 2 is arranged on one surface of the substrate 1; and the device structure area 2 comprises a first switch area, a second switch area and a logic circuit area Logical; the first switch area is used for disposing a plurality of first switches, the second switch area is used for disposing a plurality of second switches; and the first switch and the second switch are connected in series to form a plurality of high-frequency bridge arms. FIG. 2A shows the layout of the device structure area 2. In the embodiment, the first switch corresponds to an upper switch QH in the circuit shown in FIG. 1A, the second switch corresponds to a lower switch QL in the circuit shown in FIG. 1A; the corresponding first switch area is marked with QH, and the second switch area is marked by QL. In other embodiments, the first switch area can also be used for setting a lower switch QL, and the second switch area can also be used for setting an upper switch QH. The logic circuit area is configured to provide a driving signal to the first switch and the second switch. In some embodiments, the driver corresponding to the first switch or the second switch can be arranged in the logic circuit area Logical; a driving current is supplies through the driver based on the driving signal and is used for driving the corresponding switch device. A temperature sampling device, a current sampling device and other signal devices with other functions can also be arranged in the logic circuit area, and a person skilled in the art can perform corresponding arrangement according to needs. The power semiconductor wafer is provided with a long edge and a short edge, the length of the long edge in the embodiment is 5 mm, and the width of the short edge is 3.2 mm.

A DC+ electrode, a DC− electrode and a SW electrode are arranged on the power semiconductor wafer; the DC+ electrode and the DC− electrode are electrically connected with the two ends of the high-frequency bridge arm respectively, and the SW electrode is electrically connected with the midpoint end of the high-frequency bridge arm. According to the circuit topological structure of the embodiment in FIG. 1A, the upper switch QH and the lower switch QL are each of a structure in which a plurality of device structure units are connected in parallel.

In the embodiment, the first switch area is arranged in the middle of the device structure area 2 in a long strip shape, the logical circuit area is adjacent to one end of the first switch area, the second switch area is C-shaped, and the second switch area surrounds (i.e., semi-surrounds) the first switch area on three sides, that is, the lower switch QL is arranged on the periphery of the upper switch QH. Since the long direction of the strip shape of the first switch area is parallel to the long side of the power semiconductor wafer, the total length Lj of the boundary line of the first switch area and the second switch area in the layout can be set as long as possible. In the device structure area 2, after the left side and the right side are removed, the long-strip-shaped areas corresponding to the lower switch QL, the upper switch QH and the lower switch QL are sequentially arranged side by side in the direction perpendicular to the long edge, and the boundary line of the long-strip-shaped area contributes to the main part of the total length Lj of the boundary line. It is not difficult to understand that the power area SP of the DrMOS single crystal wafer and the sum of the areas of the first switch area and the second switch area is equivalent to being limited by the area of the wafer; since the power area SP can be regarded as the product of the total length Lj of the boundary line and the maximum equivalent width WL of the input loop, that is, Sp=Lj*Wl. Therefore, under the condition that the power area SP is unchanged, the longer the total length Lj of the boundary line is, the shorter the maximum equivalent width WL of the corresponding input loop is, the smaller the area of the corresponding input loop is, the smaller the input loop inductance Lloop is, and the higher the applicable frequency is. Similarly, under the wafer size of 3.2 mm*5 mm, compared with the scheme shown in FIG. 1D, the maximum equivalent width WL of the input loop of the embodiment is also 1.6 mm, and the applicable frequency can be as high as 2 MHz or even more than 3 MHz, and it is far better than the scheme shown in FIG. 1B. Moreover, in the embodiment, the number of the high-voltage areas and the number of the low-voltage areas are one (for the purpose of conveniently showing high-frequency bridge arm grouping, and the first switch area is shown in the form of two parts in FIG. 2B; and the same reasoning in the subsequent figures is not repeated), so that the method has the same advantages as the scheme shown in FIG. 1B in the aspect, and the defect that the number of partitions in the scheme shown in FIG. 1D is large is overcome. FIG. 2B shows a cross-sectional view of a power semiconductor wafer according to the embodiment. Only a high-voltage area (also referred to as a high-voltage well) needs to be dug in the device structure area 2 for manufacturing the upper switch QH. The process difficulty is low. Compared with the scheme shown in FIG. 1B, the process challenge is hardly increased, and therefore the yield and reliability of wafer manufacturing are better.

On the other hand, it can be seen that the boundary line trend of the switch areas corresponds to the repeated arrangement direction of the device structure units with the same circuit function, and the arrangement direction of parallel arrangement of the switch areas corresponds to the arrangement direction from one end to the other end of the high-frequency bridge arm. As shown in FIG. 2C, when a plurality of input decoupling capacitors Cbus are placed around the edge of the wafer, the position relationship of the high-frequency bridge arm comprising the upper switch QH and the lower switch QL is similar to that of the input decoupling capacitor Cbus due to the fact that the array trend of the input decoupling capacitor Cbus is parallel to the boundary line trend of the switch area, so that the equivalent width of the input loop is more uniform (the input loop is shown in the form of a dotted line triangle, the equivalent width of each input loop corresponds to WL, and the equivalent bottom edge length is limited by the size of the input decoupling capacitor Cbus). In the scheme corresponding to FIG. 1B to FIG. 1D, since the array trend of the decoupling capacitor Cbus is the same as the arrangement direction of the switch areas and is perpendicular to the direction of the boundary line, the equivalent width of an input loop comprising the device structure unit away from the edge is larger, the equivalent width of an input loop comprising the device structure unit close to the edge is smaller, and the different widths of the input loops can cause uneven currents at different parts. The current sharing capability of the embodiment is superior to the scheme corresponding to FIGS. 1B-1D, so that the performance is better under the same frequency, or higher working frequency can be set under the same performance. That is to say, synchronous work of each area is easier to realize in the high-frequency switch process, the reliability is greatly improved, the switching loss is reduced, and the efficiency is improved. The operating frequency of the embodiment can be higher than 2 MHz or even higher than 3 MHz.

In some other embodiments, under the concept that the switch area is formed by a long-strip-shaped area parallel to the long edge as much as possible and the high-frequency bridge arm is arranged to perpendicular to the corresponding edge of the wafer through the paralleled long-strip-shaped areas, the device structure area of the wafer can also have other layout forms so as to be suitable for more application scenes.

In a preferred embodiment, as shown in FIG. 2C, the second switch area is a long strip-shaped with an inner hole, the first switch area is a long-strip-shaped and surrounded by four sides of the second switch area (i.e., fully surrounded), and the long sides of the first and second switch areas are parallel to the long side of the wafer. Generally, the total area of the upper switch QH is set to be smaller than the total area of the lower switch QL, and is more suitable for being placed on the outer ring. The logic circuit area Logical is adjacent to the device structure unit corresponding to more lower switches QL in the full-surrounding scheme, so that the functions of current sampling and the like can be realized more conveniently, and the current sampling is generally calculated through the method of the mirror current source after sampling the device structure unit corresponding to the lower switch QL. In the embodiment, the maximum equivalent width WL of the input loop is also close to 1.6 mm, and the frequency characteristic is equivalent.

It should be pointed out that the long strip shape mentioned in the present application is not necessarily a strict rectangle, and it means that the length of one axis of the pattern is 1.1 times greater than the length of the axis in the other direction, which can become the long strip shape of the present application, especially greater than 1.5 times. Different similar shapes at the edges are, for example, racetrack-shaped, oval, and gourd-shaped, which can be seen as long-strip shapes. The parallel relation of the long-strip-shaped trend and the long edge can also be correspondingly defined as follows: the long-direction center line of the long-strip shaped is a straight line or a curve comprising multiple sections of nearly straight lines. The fitting straight line of the center line is parallel to the long side of the wafer.

In a preferred embodiment, as shown in FIG. 2D, the second switch area is C-shaped, the C-shaped opening is parallel to the long side of the wafer, the first switch area is T-shaped, and the first switch area and the second switch area are complementary in shape; so that the maximum equivalent width WL of the input loop is reserved to be close to the frequency characteristic corresponding to 1.6 mm, but the first switch area and the second switch area extend to the edge of the power area, so that electrical interconnection can be flexibly set.

In a preferred embodiment, as shown in FIG. 2E, the first switch area and the second switch area are both C-shaped, the C-shaped opening on the inner side is matched with the shape of the logic circuit area, and the logical circuit area Logical can be strip-shaped or T-shaped as shown in FIG. 2E. The outer C-shaped area surrounds the inner C-shaped area on three sides. The advantages are that the distances between the logical circuit area Logical and each device structure units of the upper switch QH and the lower switch device QL are short, so that a control driving signal is conveniently provided or current sampling is carried out. The embedding logical circuit area Logical also extends the total length Lj of the boundary line and reduces the maximum equivalent width WL of the input loop, so that the embedding logic circuit area Logical is applicable to a smaller aspect ratio of the wafer, which may even be close to a square, or better frequency characteristics may be obtained at the same aspect ratio. For example, under the same wafer size, the maximum equivalent width WL of the input loop can be reduced to about 1.4 mm, and higher working frequency is supported.

In a preferred embodiment, as shown in FIG. 2F, the semi-enclosed layout is replaced with a full-enclosed layout, that is, two semi-enclosed structures are spliced; the second switch area, the first switch area and the logic circuit area are sequentially nested in a long strip shape, the logical circuit area Logical is located in the middle, the first switch area surrounds (i.e., completely surround) the logical circuit area Logical on four sides, and the second switch area surrounds the first switch area on four sides; and the arrangement has the advantages that almost all the perimeter of the wafer is used for prolonging the total length Lj of the boundary line, so that the maximum equivalent width WL of the input loop is smaller, the maximum equivalent width WL of the input loop can be reduced to 1.3 mm, and the frequency characteristic is better. Moreover, the wafer structure is symmetrical, and extremely high flexibility is brought to subsequent packaging.

The switch area can adopt a more complex shape, so that the total length Lj of the boundary line can be longer or even exceed the perimeter of the wafer, so that the maximum equivalent width WL of the input loop is further reduced, and the aspect ratio of the wafer is optimized. In a preferred embodiment, as shown in FIG. 2G, the first switch area is C-shaped, and the second switch area surrounds the first switch area to form a hollow C shape, so that the total length Lj of the boundary line is very long, and the maximum equivalent width WL of the input circuit is small; for example, 1 mm or 0.8 mm or even lower. The logical circuit area Logical can be arranged at the opening of the hollow C-shaped opening, so that the distance between the logic circuit area and the upper switch QH is closer to that of the lower switch QL, and the signal pin can be conveniently led out. When the aspect ratio of the wafer is 1, the pair of edges of the wafer can be defined as a long side, the other pair is defined as a short side, the long side of the long strip-shaped area in the layout of the switch area is parallel to the long edge as much as possible, and the setting and the electrical connection of the decoupling capacitor can be conveniently input.

In a preferred embodiment, as shown in FIG. 2H, the first switch area is C-shaped, the second switch area does not completely surround the first switch area and only semi-surrounds the C-shaped long-striped area (and is communicated) in the direction of the C-shaped opening to form a serpentine area, the logical circuit area is also semi-surrounded by the serpentine area, the first switch area and the logic circuit area are separated by the second switch area, one side of the first switch area is located at the edge of the wafer, the scheme can also form a relatively long total length Lj of the boundary line, and the maximum equivalent width WL of the smaller input loop is very small, for example, 0.8 mm.

The Logical circuit area Logical can also be arranged along the transverse central axis of the wafer, and the power is divided into an upper part and a lower part, so that the wiring complexity is reduced, the structure is simplified, and meanwhile, the frequency characteristics are considered. Due to the fact that the length of the upper part and the lower part is constant and the width is smaller than half of the width of the wafer; the aspect ratio of the wafer can be set to be closer to 1 in a better embodiment under the layout. As shown in FIG. 2I, in the upper power area and the lower power area, the two first switch areas are adjacent to the logic circuit area respectively, and the two second switch areas respectively surround the first switch area on three sides. Due to the fact that the second switch area is C-shaped with a shallow opening, the half-surrounded layout mainly makes full use of the length of the long edge of the wafer, the contribution of the surrounding areas on the two sides to the total length Lj of the boundary line is small, and the maximum equivalent width WL of the input loop in the embodiment is 1.5 mm.

In a preferred embodiment, as shown in FIG. 2J, similar to FIG. 2I, the maximum equivalent width WL of the input loop in the embodiment is 1.5 mm, but the first switch area and the second switch area no longer have a surrounding or surrounded relationship, but are completely in a strip-shaped parallel arrangement relationship, and compared with the layout shown in FIG. 2I, the layout is simpler.

In a preferred embodiment, as shown in FIG. 2K, the power area is also divided into an upper part and a lower part by a logic circuit area Logical arranged along the transverse central axis, and in each part, the second switch area surround the first switch area on four sides. The strip-shaped first switch area is used for setting an upper switch QH, and the second switch area is used for setting a lower switch QL. For a wafer size of 3.2 mm×5 mm, the maximum equivalent width WL of the input loop has an opportunity to approach 0.6 mm or even lower.

For an application scene whose frequency is not particularly high, for example, when the working frequency is between 1 MHz and 3 MHz, the embodiment under the simplest layout meeting the concept of the application can be adopted. As shown in FIG. 2L and FIG. 2M, in a preferred embodiment, the logic circuit area is located on one side of the long side or the short side of the wafer in the device structure area 2 and is parallel to the strip-shaped power area, the power area is divided into two parts along the long side direction to form two parts, the first switch area and the second switch area are respectively used for setting the upper switch QH and the lower switch QL; when the wafer is applied, the input decoupling capacitor Cbus is arranged in the long side direction, and the maximum equivalent width WL of the input loop corresponding to FIG. 2L and FIG. 2M is 2.5 mm and 3.2 mm respectively.

Although the embodiment takes Buck as an example, the method is also suitable for other high-frequency bridge circuits, and in particular, at least two power switch devices (denoted as an upper switch QH and a lower switch QL) which are connected in series in the bridge circuit are integrated on one wafer by using a single crystal wafer process, so that high-frequency work is realized. The single crystal wafer process can be a Silicon, GaN or Silicon and GaN mixing process, or other materials or processes integrating device structure units capable of manufacturing various functions on one wafer.

### Embodiment 2

When the high-frequency bridge arm works, at least one of the switching devices in the whole process or occasionally works at high-frequency hard switch, so that the capability of the driver for driving the high-frequency bridge arm can influence the switching loss of the device. The driving current provided by the driver to the switching device working on the hard switch can generate corresponding time characteristic distribution difference due to the difference of circuit lengths corresponding to different device structure units, and the difference can influence the switching synchronism of different device structure units of the switching device. Therefore, the preferred design is that the driver is close to the switching device working on the hard switch as much as possible and is uniformly distributed as much as possible. For the BUCK circuit, the upper switch QH is a switch device working at hard switch. For the BOOST circuit, the lower switch QL is a switch device working at hard switch. For the Buck-Boost bidirectional working circuit, the upper switch QH and the lower switch QL work at hard switch.

Therefore, in the embodiment, in order to guarantee the high-frequency characteristic, the driving area Driver is specially divided in the device structure area 2, the driver area Driver is distributed in the power area, and the driver area Driver is at least adjacent to each area of the switching device works at hard switch in the power area and is uniformly distributed.

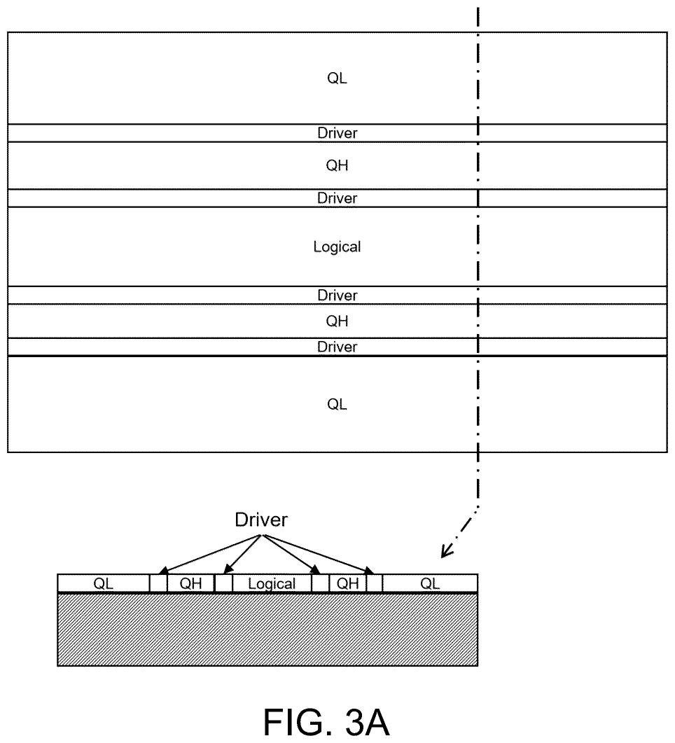

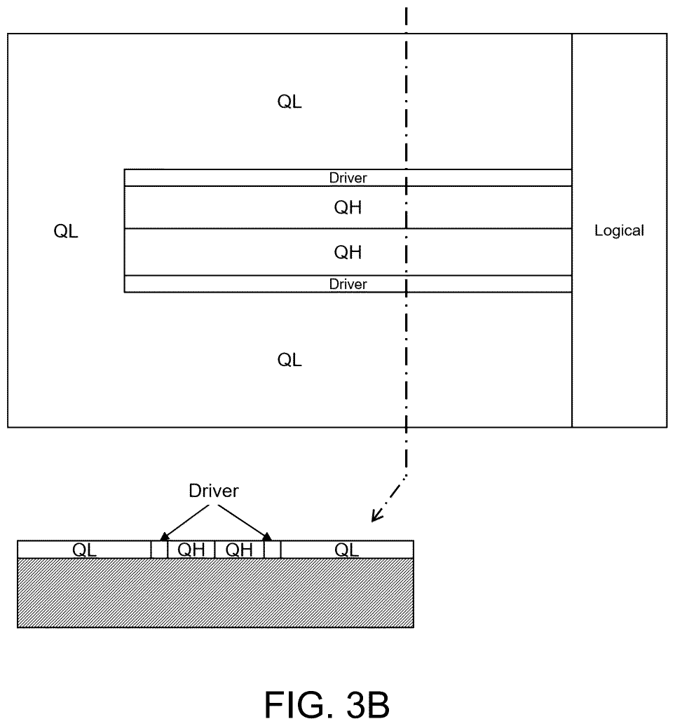

FIG. 3A shows a structure of a power semiconductor wafer of the present embodiment. The logical circuit area Logical and each switch area in FIG. 3A are parallel to the long side of the wafer. For a wafer for a Buck circuit, a first switch area of an upper switch QH and a driving area Driver are arranged adjacent to each other, and the length of the driving area is close to that of the first switch area so as to realize nearby balanced driving. In FIG. 3B, the logical circuit area Logical is on one side, and the driving area Driver is arranged on the two sides of the adjacent long edge of the first switch area, so that the effect similar to the scheme in FIG. 3A is achieved. Since the current provided by the logic circuit area Logical to the driving area Driver is only a small driving signal current, the arrangement of the logic circuit area Logical and the driving area Driver does not significantly affect the driving effect. In a cross-sectional view, it can be seen that areas with different functions need to be isolated in a device structure area through a semiconductor process, and the areas are respectively used for setting at least four types of devices such as an upper switch QH, a lower switch QL, a driver and other logic circuits. The more areas, the smaller the maximum equivalent width WL of the input loop corresponding to the high-frequency bridge arm in the short side direction of the wafer is, the better the high-frequency characteristic is, and the more complex the corresponding manufacturing process is. Therefore, according to the embodiment of the application, trade-off design can be carried out on high-frequency performance and complexity through different layout adjustment, and different application scenes of stages in the market, recent future and long periods in the future are met. Obviously, the driving of the lower switch QL can also be arranged nearby and arranged in parallel, so that better driving performance of the lower switch QL is realized. According to the driver of the embodiment, only one driver of the upper switch QH or the lower switch QL can be arranged; or drivers of the upper switch QH and the lower switch QL can also be arranged at the same time.

According to the embodiment, the layout division of the first switch area, the second switch area and the logic circuit area can be carried out directly or be carried out with analogized and/or combined according to any one of the embodiments of the first switch area, the second switch area and the logic circuit area. According to the embodiment and the area division of the first embodiment, each functional partition is arranged and illustrated in the device structure area on the wafer substrate so as to be realized:
1, different loop inductance values are realized in a power area, and different degrees of subdivision and arrangement of the upper switch QH and the lower switch QL are carried out, so that the manufacturing complexity and the high-frequency characteristic of the wafer are balanced;
2, arranging different forms of arrangement matching on the power area and the logic circuit area, so as to balance the high-frequency characteristics of the power area, the aspect ratio of the wafer and the convenience of leading out the signal pin;
3, the driving area Driver of the switching device is further arranged, so that the high-frequency equalization driving characteristic is realized.

Obviously, the advantages brought by each of the three aspects to the single crystal wafer integrated device can be combined with each other and are not limited to the embodiments shown above.

### Embodiment 3

The embodiment further shows a wiring structure from the device structure area of the power semiconductor wafer to the electrode. The arrangement of the device structure area of the wafer lays a foundation for the high-frequency performance of the wafer. However, each functional area of the device structure area of the wafer, in particular, the current collection of the power area, only depends on the electrical interconnection inside the semiconductor material is not enough. The wiring layer of the RDL wiring layer or the packaging substrate is required to realize the current collection with low-impedance interconnection of each part of the semiconductor area. Therefore, the wiring structure also needs to be optimized and designed for different functional area layouts. According to the embodiment of the application, the first switch area and the second switch area are mainly formed by long-strip-shaped areas parallel to the long edge, and a surrounding structure is usually formed at the edge or the corner of the short edge, so that the layout design of the bus wiring layer can be provided for the sub-areas 3 of the surrounding type and the sub-areas 4 of the parallel repeating units respectively. The sub-areas 4 of the parallel repeating units can be divided into sandwich-shape and double-layers-shape, and the better bus wiring layer structure corresponding to most schemes in the embodiment can be obtained through the combination of various sub-areas 3/4.

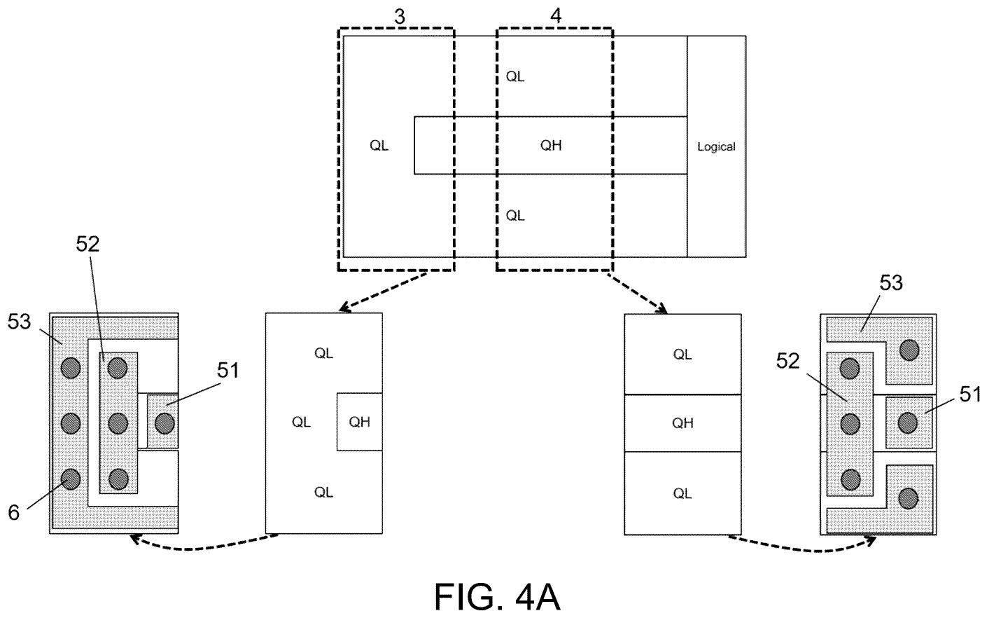

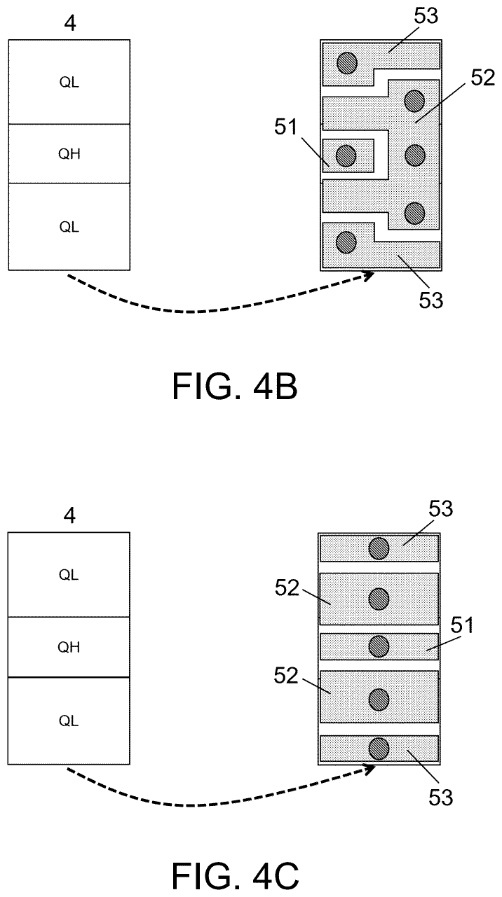

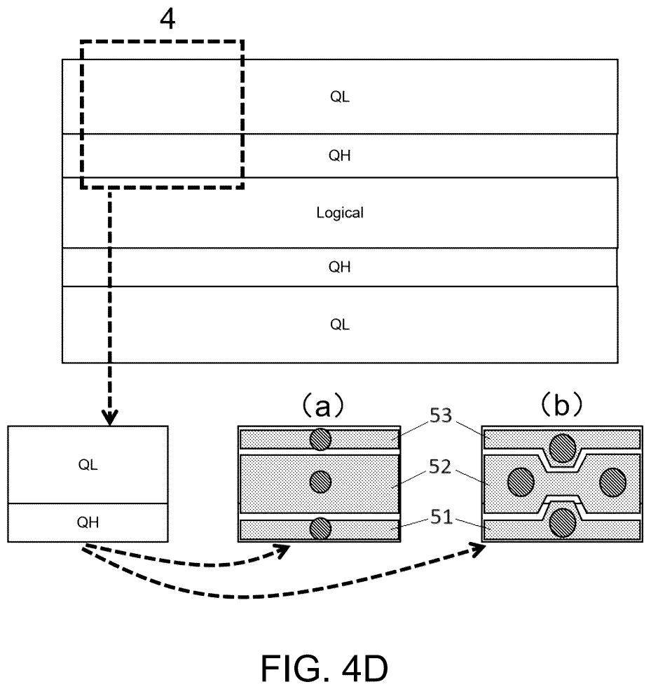

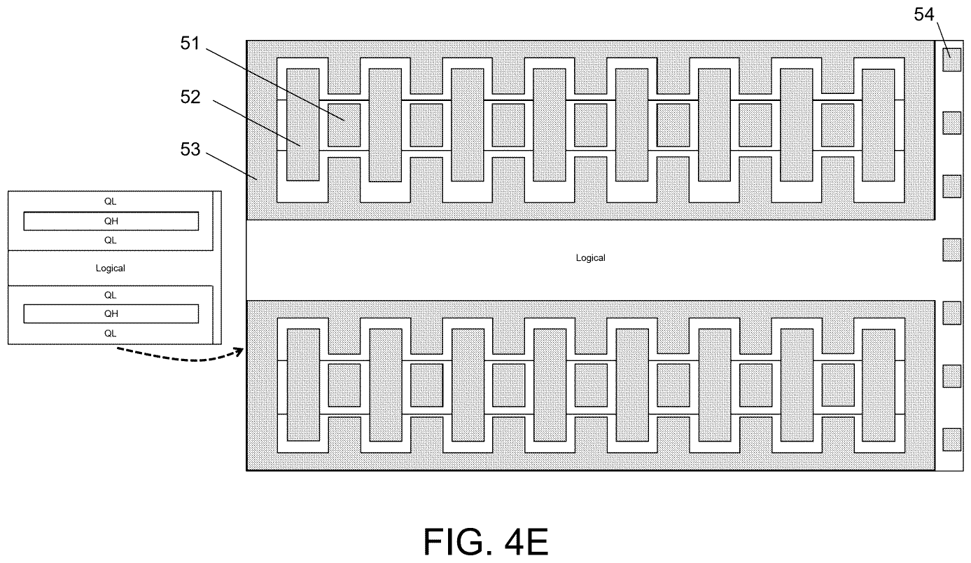

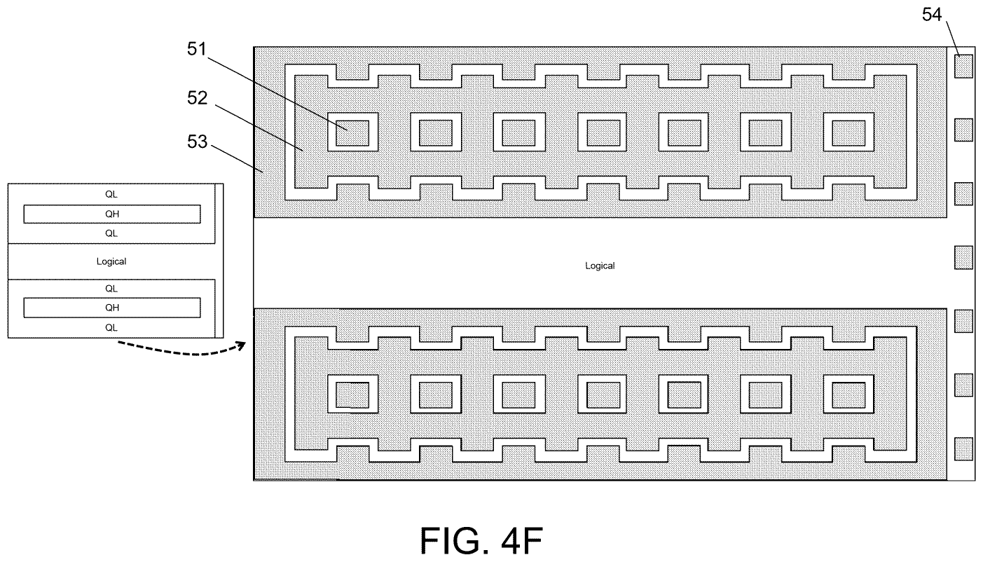

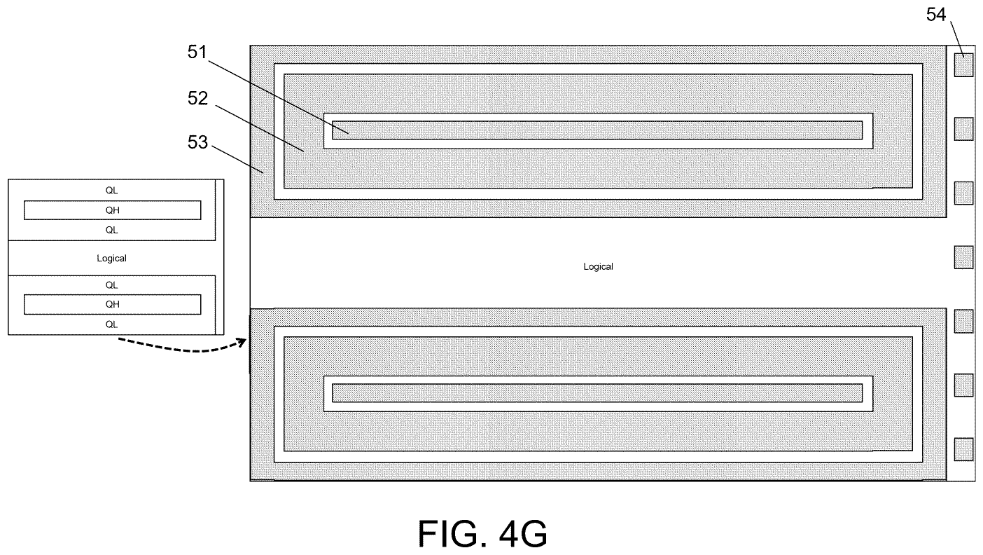

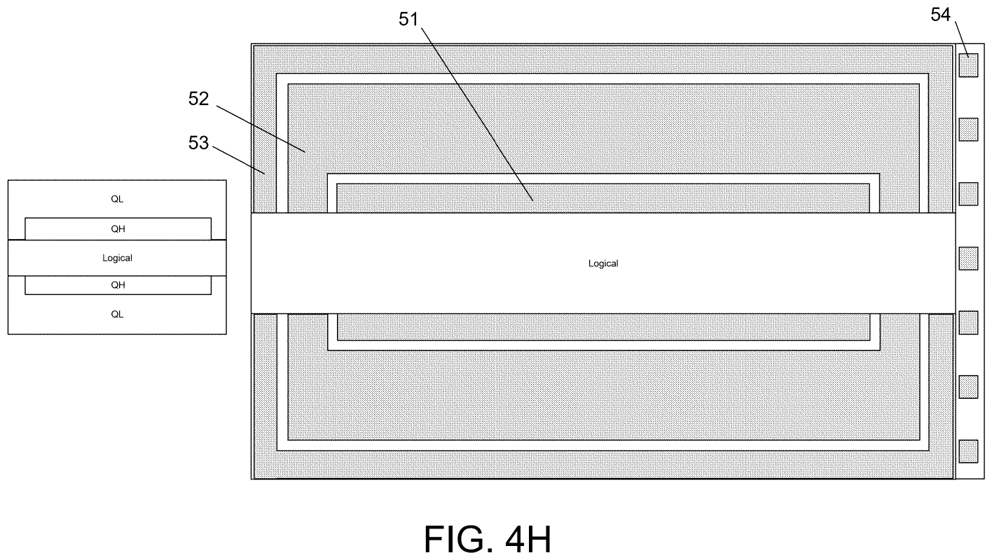

A surrounding sub-area 3: one of the first switch area and the second switch area two-side surrounds (i.e., the corner surrounds, equivalent to the corner of the four-side surrounding or three-side surrounding structure) or three-side surrounding (semi-enclosed) the other one. The left lower diagram of FIG. 4A shows the situation that the second switch area corresponding to the lower switch QL surrounds the first switch area corresponding to the upper switch QH on three sides.

A sub-area 4 of the parallel repeating unit: The first switch area and the second switch area are arranged in parallel in the sub-area. The wiring structure of the sub-area can be used as a repeating unit to be repeated side by side, so a longer area wiring structure is formed. A sandwich-shape or a double-layer-shape is usually formed, and the structure of more layers can be obtained through analogy. As shown at the lower right of FIG. 4A, the second switch area corresponding to the lower switch QL sandwiches the first switch area corresponding to the upper switch QH from above and below to form a sandwich-shaped sub-area.

The lower view of FIG. 4D shows the case of a double-layer sub-area with only one layer of the first switch area and one layer of the second switch area. For a surrounding sub-area 3, a wiring bus is a wiring area 51 (corresponding to one of a DC−/DC+ electrode, the wiring area 51 is electrical connected with a high-voltage terminal of an upper switch QH, and a DC+ electrode in the present embodiment), a wiring area 52 (corresponding to an SW electrode, the wiring area 52 is electrical connected with the midpoint terminal of a high-frequency bridge arm and an SW electrode) and a wiring area 53 (corresponding to the other of the DC−/DC+ electrode, the wiring area 53 is electrical connected with a low-voltage terminal of a lower switch QL and a DC− electrode in the present embodiment). The SW electrode is maximum in current in all the electrodes, and can be achieved by the wiring crossing the switch areas to obtain the high-current interconnection with the lowest impedance. A bus lead-out piece 6 (which can be a lead-out Pad or a lead-out Via) corresponding to each electrode is arranged on a corresponding wiring area 51/52/53, so that the transmission of current with the externality can be realized.

Wherein the total sectional area of the current conduction of the bus lead-out piece 6 corresponding to the SW electrode is larger than that of the DC− electrode or the DC+ electrode, so that the current density of each current channel is balanced, and the minimum current circulation loss is realized.

For the sub-area 4 of the sandwich-shaped parallel repeating unit, there may be several different arrangements for different application scenarios.

One embodiment as shown in the lower right diagram of FIG. 4A is suitable for occasions where the maximum equivalent width WL of the input loop is narrow. Due to the fact that the maximum equivalent width WL of the input loop is narrow, in the longitudinal column direction, the bus lead-out piece 6 that can be arranged in the same column is limited, and only three wiring areas which are separated from each other and three bus lead-out piece 6 can be arranged in the same column. Therefore, in the left side of the sub-area 4, the wiring area 52 spans the first switch area of the sandwich middle layer and can be interconnected nearby with the second switch area of the upper and lower layers and the second switch area of the middle layer. The length of the wiring area 52 in the longitudinal direction should be greater than 50% of the length of the sub-area 4. In the right side of the sub-area 4, the wiring areas 53, the wiring areas 51 and the wiring areas 53 which are separated from each other are respectively electrically connected to one layer of a sandwich-shaped layer, and the wiring areas 53 between adjacent sub-areas 4 are transversely connected to one another around the wiring area 52. Each wiring layer is provided with a bus lead-out piece 6.

One embodiment as shown in FIG. 4B is suitable for situations where the maximum equivalent width WL of the input loop is centered. In the longitudinal direction, five wiring areas spaced apart from each other and three bus lead-out piece 6 can be arranged in the same column. Compared with the wiring structure in FIG. 4A, the wiring area 52 can bypass the wiring area 51 from the two sides, extend between the wiring area 51 and the wiring area 53, and are transversely connected into one piece, so as to reduce the bus impedance on the SW electrode as much as possible.

One embodiment as shown in FIG. 4C is suitable for situations where WL is wider. Five wiring areas apart from each other and five bus leading-out pieces 6 can be arranged in the longitudinal column direction, so that the wiring layers can be arranged in parallel. The five wiring areas in the longitudinal direction are sequentially a wiring area 53, a wiring area 52, a wiring area 51, a wiring area 52 and a wiring area 53. Each wiring area 51/52/53 is respectively provided with a corresponding bus lead-out piece 6. The wiring structure enables the device structural units of the power area to be interconnected to the bus lead-out piece 6 through relatively consistent impedance, so that the minimum bus impedance is realized. Of course, each wiring area 51/52/53 is not necessarily equal in width in the transverse direction. The form of (B) in FIG. 4D can also be adopted; the bus lead-out piece 6 corresponding to the wiring areas 52 are arranged in a staggered manner in the longitudinal direction, the position of the wiring areas 51/52/53 on the bus lead-out piece 6 is wide, and the spacing position of the bus lead-out piece 6 is narrow, so as to achieve the balance between the lead-out pieces setting and the bus impedance.

FIG. 4D shows the arrangement of the wiring structure in the sub-area 4 of the double-layer parallel repeating unit. The wiring area 53, the wiring area 52 and the wiring area 51 corresponding to the DC−, SW and DC+ respectively in the FIG (a) are sequentially arranged in parallel, the wiring area 52 is located at the junction of the first switching area and the second switching area. Each wiring area 51/52/53 is respectively provided with a corresponding bus leading-out piece 6; in the FIG (b), the bus lead-out piece 6 corresponding to the wiring area 52 and the bus lead-out piece 6 corresponding to the wiring area 51/53 are staggered in the longitudinal direction, the wiring area 51/53 is wider at the position where the bus lead-out piece 6 is arranged, and the interval position is narrow, so that the wiring area is reasonably transferred to the wiring layer 52, and the minimum bus impedance and loss of the SW electrode are realized.

FIG. 4E to FIG. 4H show several structures formed by combining a plurality of sub-areas to form a complete bus wiring layer. The bus lead-out piece 6 is not shown in each figure, obviously, on the premise that the process precision requirement is met, the bus lead-out piece 6 can be arranged as dense as possible, the bus wiring layer can be subjected to shape fine adjustment according to the shape of the bus lead-out piece 6, the wiring area with the position of the bus lead-out piece 6 is locally widened, and other positions are locally narrowed.

FIG. 4E to FIG. 4G are three bus wiring layer structures corresponding to the same device structure area layout (left image). The complete power area is composed of a semi-enclosed sub-area 3 and a sub-area 4 of a sandwich-shaped parallel repeating unit. For a power area composed of only a semi-enclosed sub-area 3 or only a sub-area 4 of a sandwich-shaped parallel repeating unit, a corresponding bus wiring layer structure can be obtained by analogy, and is not to list further here. For the combined complete bus wiring layer, the percentage of the occupied area of the wiring area 51 corresponding to the DC+ electrode is the minimum, usually less than 20%; the proportion of the wiring area 52 corresponding to the SW electrode is the largest, and is usually greater than 40%; and the area of the wiring area 53 corresponding to the DC− electrode is usually greater than 20%. Preferably, the device structure area can adopt a logic circuit area Logical to divide the power area from the middle into two parts, the aspect ratio of each power area is larger. The combination is that multiple types of areas of the wafer are sequentially arranged, the electrical connection distance is shorter, a high-frequency low-loop circuit is achieved, and low-impedance large-current is also achieved.

FIG. 4H is a bus wiring layer structure corresponding to another device structure area layout (left image). The complete power area is composed of a corner surrounding sub-area 3 and a sub-area 4 of a double-layer parallel repeating unit. A corresponding bus wiring layer structure can be obtained by analogy for a power area comprising only a corner surrounding sub-area 3 or a sub-area 4 of a double-layer parallel repeating unit, and the corresponding bus wiring layer structure is not to list further here. Preferably, the device structure area can adopt a logic circuit area LogicalL to divide the power area from the middle into two parts, the aspect ratio of each power area is larger. The first switch area and the second switch area of each power area are long-strip-shape and are arranged in parallel with the long edge of the wafer. The first switch area corresponding to the upper switch QH is close to the logical circuit area, that is, is located on the inner side. The second switch area corresponding to the lower switch QL is close to the edge of the wafer, that is, is located on the outer side. The corresponding bus wiring layer of each power area is a long-strip-shaped wiring layer 51 corresponding to the DC+ electrode, a long-strip-shape wiring layer 52 corresponding to the SW electrode and a long-strip-shaped wiring layer 53 corresponding to the DC− electrode from the transverse central axis to the outside. Definitely, in some other embodiments, the long-strip-shaped wiring area can also be in a shape similar to a dash line type, so that the wiring area on the inner side extends to the edge of the long edge, and lateral electrical connection is facilitated. The signal pins of the logical circuit area can be arranged at the transverse central axis of the wafer and can also be led to the outer side of the short side of the wafer.

### Embodiment 4

A closed loop is formed only after the high-frequency bridge arm and the input decoupling capacitor Cbus need to be connected in parallel. Aiming at the high-frequency use scene, the application is crucial to the electrical interconnection of the input decoupling capacitor Cbus, and the embodiment shows the specific mode of assembling the power semiconductor wafer of the single crystal wafer integrated power bridge arm and the input decoupling capacitor Cbus to form the module.

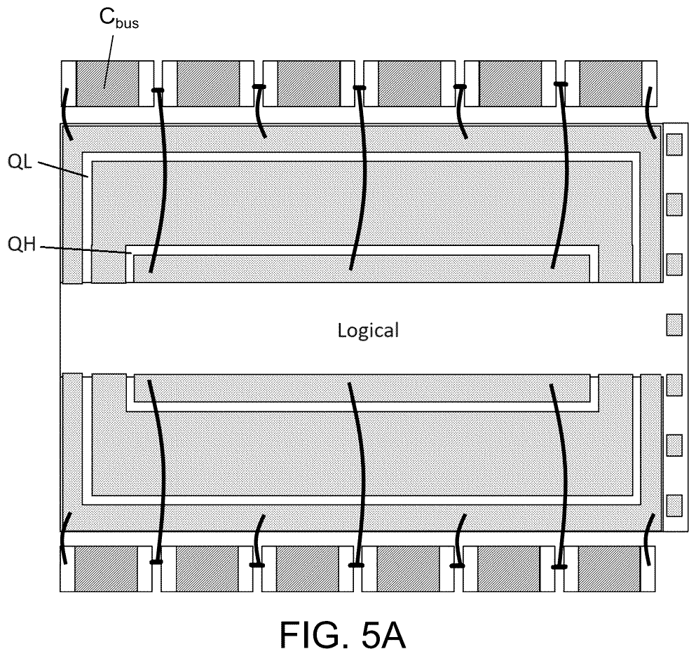

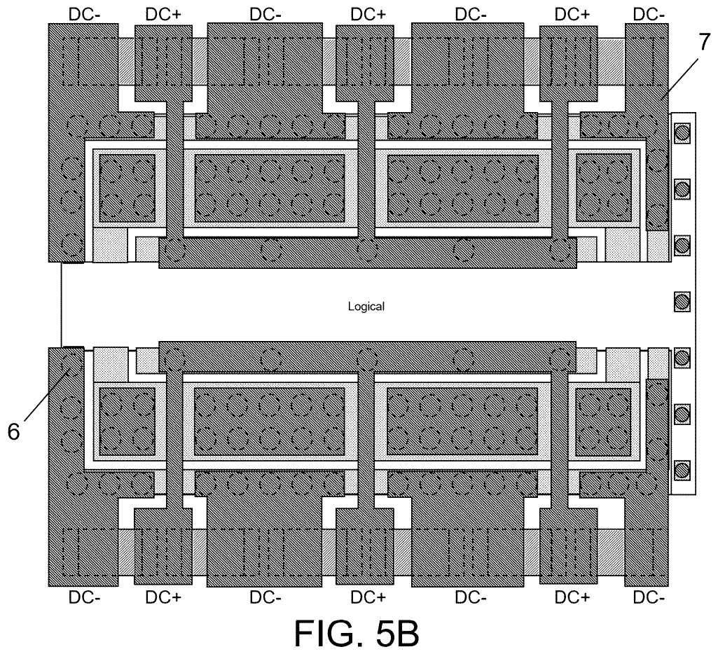

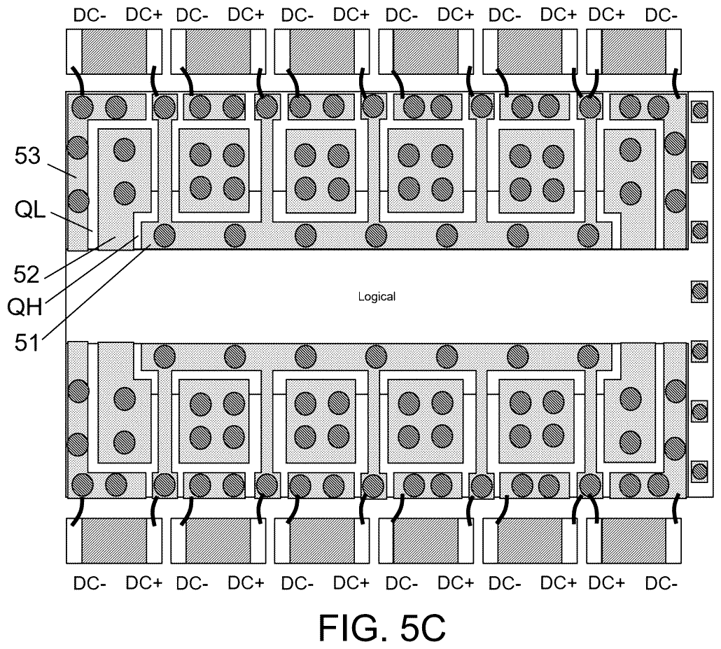

As shown in FIG. 5A, in order to enable each device structure unit of the power semiconductor wafer to obtain the decoupling of the input decoupling capacitor Cbus as close as possible, a long-strip-shaped array composed of a plurality of capacitors is arranged on the outer side of the long side of the power semiconductor wafer. The direction of each capacitor and the electrical connection wiring of the wafer is perpendicular to the long side of the wafer, that is, parallel to the short side, so that the two ends of each capacitor are electrically connected with the DC+ electrode and the DC− electrode respectively. The total inductance Lloop of the input loop formed by the input decoupling capacitor Cbus and the high-frequency bridge arm is formed by a plurality of small loops in parallel, so that the overall total inductance is very small. Moreover, two capacitor arrays are symmetrically arranged on the outer sides of the two long sides, so that the total input loop inductance Lloop can be further reduced. Generally, a capacitor array is formed by combining a plurality of small-size multilayer ceramic capacitors through a substrate and is electrically connected to the wafer.

Since the capacitor array has a number of pins that need to be electrically connected with the DC+ electrode or the DC− electrode of the wafer, one of the pins (e.g., DC+ electrode) is usually arranged in the middle of the wafer. Therefore, as shown in FIG. 5B, in the capacitor interconnection wiring layer 7 (the capacitor interconnection wiring layer 7 can be arranged on the substrate of the module), the longitudinal wiring corresponding to the DC+ electrode cuts off the wiring segments corresponding to the DC− electrode and the SW electrode into dashed lines. Due to the fact that the longitudinal wiring can be arranged to be thin, as long as sufficient area of each section of the dotted line is ensured to be used for arranging the bus lead-out piece 6, the interconnection impedance is hardly influenced, and meanwhile, the ultra-low loop inductance is achieved.

In the capacitor array shown in FIG. 5A, two adjacent capacitors are arranged in opposite electrical directions, that is, the electrical properties of adjacent electrodes are the same, for example, corresponding to a DC+ electrode or corresponding DC− electrode, so that the required wiring quantity is smaller, and the wiring layer resources can be more fully utilized. Moreover, the electrical properties of adjacent electrodes are the same, the capacitors can also be more compact, and the space is fully utilized. Only from the input loop inductance Lloop, the input loop inductance Lloop in FIG. 5C can be smaller than that in FIG. 5A, but the electrical properties of two adjacent electrodes of two adjacent capacitors are different, the requirement for wiring is higher, and the method is suitable for a scene with higher working frequency. The wiring area 51/53 in FIG. 5C respectively leads the DC+ electrode and the DC− electrode to the long side edge of the wafer and sets a corresponding bus lead-out piece, the wiring area 52/53 of the bus wiring layer directly forms a transverse multi-section dotted line shape.

### Embodiment 5

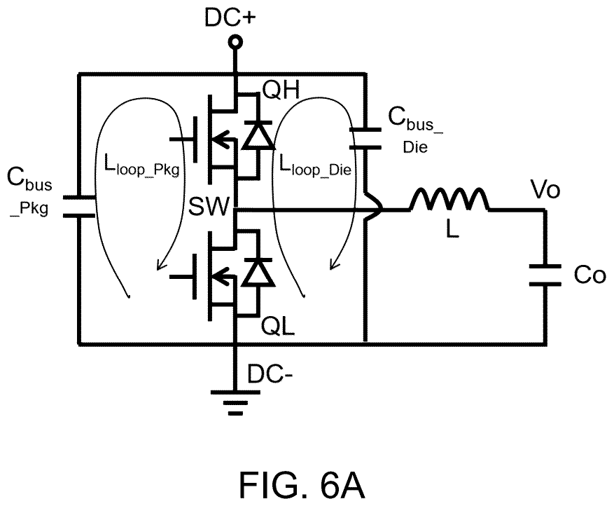

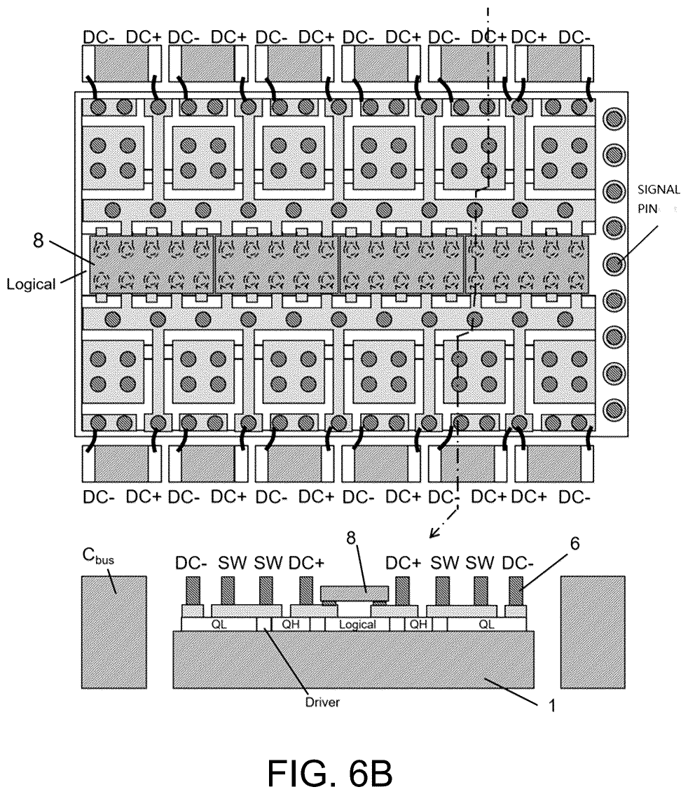

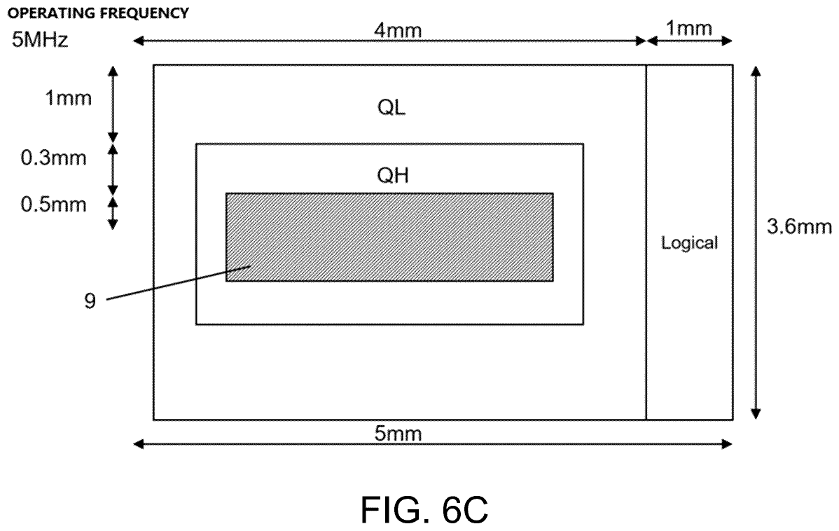

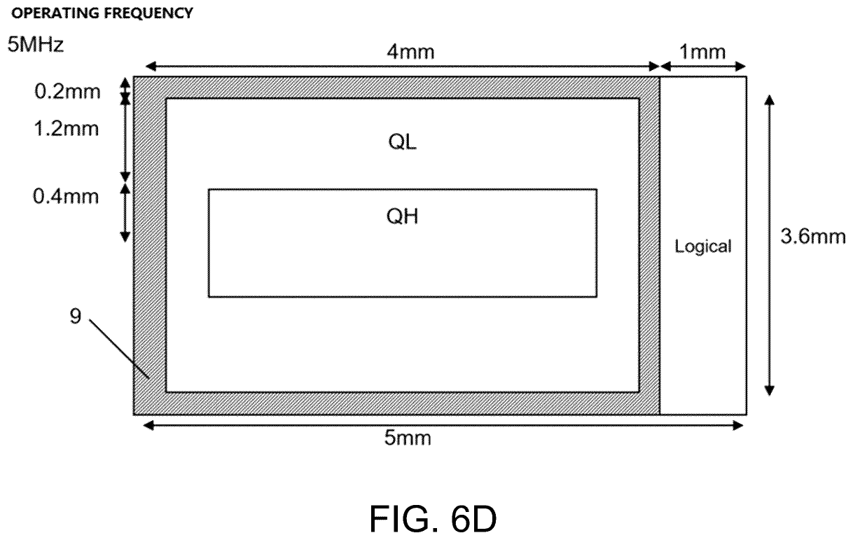

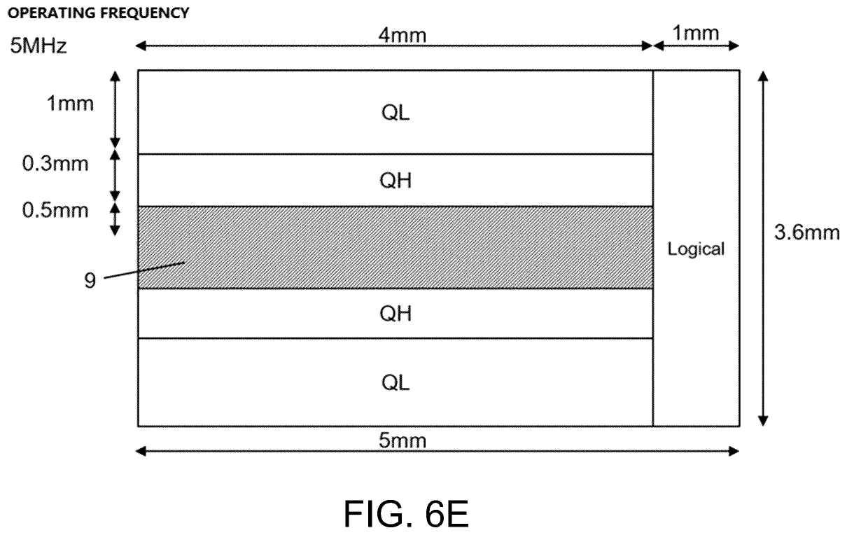

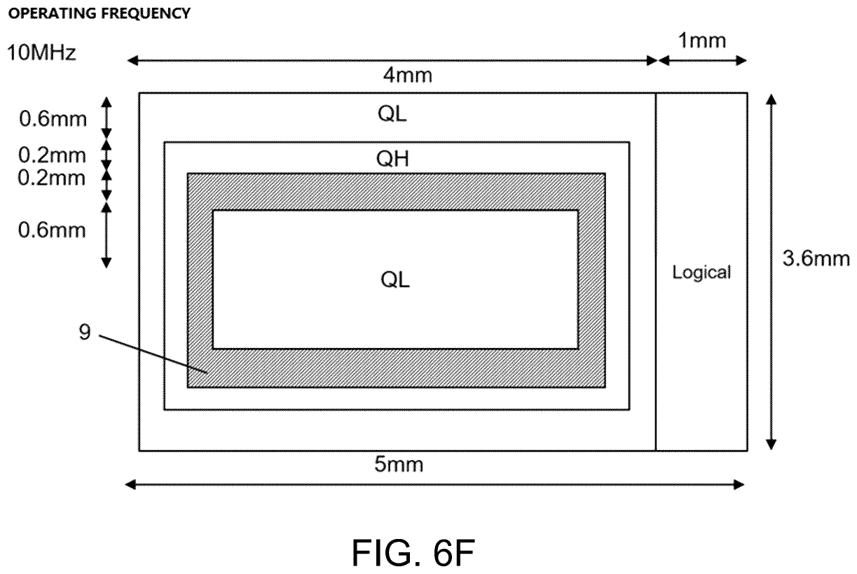

In the scheme of the fourth embodiment, the total input loop inductance Lloop can be as low as less than 0.5 nH. However, when the working frequency is very high, for example, higher than 2 MHz or even higher, only the input loop formed by the external decoupling capacitor C_{bus_Pkg} is not ideal enough, and a wafer integrated capacitor C_{bus_Die} needs to be arranged on the wafer or in the wafer. As shown in FIG. 6A, the outer decoupling capacitor C_{bus_Die} and the wafer integrated capacitor C_{bus_Pkg} are respectively connected with the high-frequency bridge arm in parallel to form two loops, and the total equivalent inductance L_{loop_Pkg} of the outer decoupling capacitor and the total equivalent inductance L_{loop_Pkg} of the wafer integrated capacitor loop play a multi-stage decoupling effect. In this way, the equivalent total inductance is reduced to be lower. The chip integrated capacitor is divided into two types, one is a wafer with built-in capacitor, and one is the power semiconductor wafer with the laminated decoupling capacitor 8.

In a preferred embodiment, as shown in FIG. 6B, the wafer integrated decoupling capacitor 8 adopts a capacitor having array pins, such as a silicon capacitor, soldered to the wafer. Therefore, a capacitor connection pad corresponding to the silicon capacitor pin needs to be reserved on the surface of the wafer. Due to the fact that the current density of the wafer is very high, the influence of the metal layer on the surface of the wafer on the through-flow capacity is very large, the conventional wafer layout and the capacitor connection bonding pad occupy the resources, and the loss is increased. However, in the embodiment, the logical circuit area Logical is transversely arranged on the central axis of the wafer, so that the capacitor connecting bonding pad can be arranged in the area corresponding to the logical circuit area Logical in the bus wiring layer, so that the silicon capacitor is also arranged at the corresponding position, and the wiring resource can be reserved for the silicon capacitor because the logic circuit area Logical does not need large current wiring. On the basis of the arrangement of the wafer and the outer decoupling capacitor shown in FIG. 5C, an equivalent long-strip-shaped silicon capacitor composed of a long-strip-shaped silicon capacitor or a plurality of silicon capacitors is placed on the transverse long-strip-shaped part of the long-strip-shaped logic circuit area, and an electrical connection structure such as a corresponding wiring is arranged on the bus wiring layer of the wafer. The pins of the long-strip-shaped silicon capacitor are electrically and alternately arranged in the long-side direction and are connected with the circuit nodes corresponding to the DC+ electrode and the DC− electrode in each power area, a plurality of small Loops are formed and are equivalent to each other in parallel, and the total equivalent inductance L_{loop_Die} of the small wafer integrated capacitor loop is realized. Preferably, the thickness of the silicon capacitor can be set to be thinner than 0.1 mm or even 0.05 mm so as to better lead out the power or signal pin of the wafer.

As shown in FIG. 6B, a pre-formed laminated decoupling capacitor is subjected to power level interconnection with a power semiconductor wafer in a welding or electroplating mode, that is, a Cap On Die process, and the integration mode is relatively high in packaging difficulty and relatively inflexible. In some other embodiments, a Cap In Die process may also be used, that is, a capacitor is a wafer built-in capacitor formed in situ during a production process of a wafer, for example, a device area capacitor is formed in a device structure area of a wafer by means of processes such as etching, or a built-in layered capacitor is formed between two or more wiring layers by arranging the dielectric layer. Because it's the semiconductor process, the precision is high, and the method can be flexibly set.

In a preferred embodiment, as shown in FIG. 6C, a built-in capacitor area 9 is further arranged in the device structure area. The built-in capacitor area 9 is arranged in the middle of the power area, and the first switch area and the second switch area are sequentially arranged on the four sides in a surrounding mode, so that the working frequency can be improved to 5 MHz. In a preferred embodiment, as shown in FIG. 6D, the built-in capacitor area 9 surround the power area on four sides, and the power area is also of a structure surrounded on four sides, so that the influence on the wiring of the power area can be reduced. In a preferred embodiment, as shown in FIG. 6E, the built-in capacitor area 9 is arranged in a long strip shape along the transverse central axis, and the first switch area and the second switch area in the power areas on the two sides are also long-strip-shaped parallel to the long edge. In some other embodiments, a combination of the solutions in FIG. 6C and FIG. 6D may also be used, a built-in capacitor area 9 is provided in both the center and the periphery of the power area, the loop inductance is further reduced, and a higher frequency, such as up to 10 MHz application is achieved. The built-in capacitor area 9 in each embodiment is also mainly formed by a long strip-shaped area, and the trend of the strip shape is parallel to the boundary line trend of the first switch and the second switch and is as long as possible.

As shown in FIG. 6F, in the power area, the second switch area, the first switch area and the second switch area respectively corresponding to the lower switch QL, the upper switch QH and the lower switch QL are distributed in a surrounding mode, so that a longer total length Lj of the boundary line and a smaller maximum equivalent width WL of the input circuit are achieved, and the frequency performance is improved. The built-in capacitor area 9 is arranged between the two second switch areas and surrounds a circle in the same strip-shaped trend. The working frequency higher than 10 MHz can be realized. Further, another built-in capacitor area is further arranged on the outside of the outer power area or in the center of the inner power area, so that higher working frequency can be achieved, and even higher than 20 MHz.

The arrangement of the built-in capacitor area and the layout of the power area and the logic circuit area Logical can be combined with each other in various forms, and the implementation modes are many, and are not limited to the provided examples. In essence, the long-strip-shape areas of the first and second switch areas form a boundary line as long as possible, and the long-strip-shape area of the built-in capacitor area 9 also forms the same direction as the long-strip-shape area of the first/second switch area and as long as the boundary line as possible. More preferably, a plurality of built-in capacitor areas 9 can be provided, which are respectively adjacent to different switch areas, such that the device area capacitors are respectively adjacent to the high-voltage end and the low-voltage end of the high-frequency bridge arm and are connected in parallel with the high-frequency bridge arm.

The arrangement of the built-in capacitor is not limited by the position of the logic circuit area. When the logical circuit area Logical is arranged at the transverse central axis, a Cap On Die scheme is adopted, so that a pre-formed capacitor can be used on the premise of almost not occupying the power wiring resources in the wafer, and larger capacitance is achieved.

However, when the logical circuit area Logical is set in the middle, in order to more fully utilize the space, the logical circuit area Logical becomes very long and narrow, so that some functional units in the area are far away from signal pins, the impedance and the inductive reactance are relatively large, and a certain influence exists on pins, such as power supply pins, needing to be connected with a high-frequency capacitor on the pins. Whether the Cap on Die or the Cap in Die or the capacitor is formed by combining a plurality of independent small capacitor units. Therefore, the small capacitor units can be combined into a chip integrated capacitor C_{bus_DIE}, and meanwhile, part of the area can be allocated to be set and combined into a capacitor required by logical circuit area Logical, such as a logic circuit area power supply decoupling capacitor. In this way, high-frequency work of the power area is achieved, and reliable work of the logical circuit area Logical is also achieved.

For the situation that the chip integrated capacitor C_{bus_Die} is integrated in the wafer or the on the surface of the wafer in the embodiment, when the power supply module is formed, the long side edge of the wafer is integrated with more outer side decoupling capacitors C_{bus_Pkg} through packaging or a substrate, and the multi-stage loop inductance decoupling effect is achieved. The equivalent total capacitance value of the chip integrated capacitor C_{bus_Die} should be greater than five times of the sum capacitance of the upper switch QH and the lower switch QL, and less than 0.2 times of the equivalent total capacitance value of the outer decoupling capacitor C_{bus_Pkg}, and the total equivalent inductance L_{loop_Die} of the wafer integrated capacitor loop formed by the wafer integrated capacitor C_{bus_Die} and the high-frequency bridge arm should be smaller than 0.7 times of the total equivalent inductance L_{loop_Pkg} of the outer side decoupling capacitor C_{bus_Pkg} and the high-frequency bridge arm so as to form an effective composite multi-band decoupling effect.

### Embodiment 6

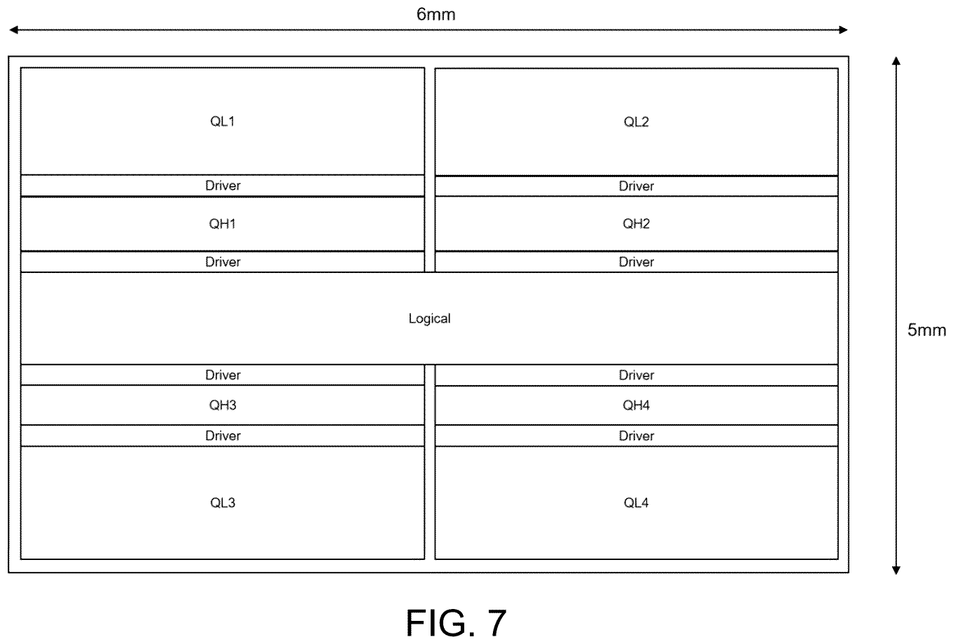

FIG. 7 shows a layout of a device structure area in the present embodiment. In some embodiments, the logical circuit area Logical divides the power area into a plurality, for example, two, from the middle, so that the separated two power areas can receive different control drive signals to independently work. The power area of each part can be an independent half-bridge, can also be connected in parallel to realize larger synchronous current; and can also be two circuits with staggered 180 degree control or a full-bridge circuit with staggered-phase control. In the high-frequency scene, each power area can be further divided into two independent parts, and the single crystal wafer have four independent power areas, so that four circuits controlled by signals with 90-degree staggered phase are realized, and higher-frequency staggered phase transformation is realized. Due to the fact that the single crystal wafer is integrated with a plurality of circuits, the integration level of the power unit is higher, the total number of signal pins can be reduced, and the complexity of the system is reduced. For example, when four circuits are integrated, the number of signal pins corresponding to the functions of power supply, current sampling, temperature sampling and the like of the logic area is reduced to one time from four times. In addition, in actual use, the power area is placed nearby, the current on each power pin is staggered nearby the packaging substrate, the high-frequency current components of the power pins and the wires of the DC+ electrode and the DC− electrode are greatly reduced and counteracted, and the loss is reduced.

In summary, in various embodiments, through the arrangement of the upper switch QH and the lower switch QL in the power area, the minimum WL, the longest U and the logic circuit area Logical interpenetration in the power area are used for reducing the aspect ratio, increasing the yield rate of the wafer, or realizing smaller WL and longer Lj with the same aspect ratio, and the partition driver realizes high-frequency synchronous driving, the chip integrated capacitor is arranged to realize a minimum loop, the internal and external decoupling capacitors are matched to realize multi-band decoupling, and the area utilization of the bus wiring layer and the small power loop is considered through the overlapped position between the laminated capacitance and the logical circuit area Logical, single crystal wafer multi-circuit work and the like, the performance of a power semiconductor wafer integrated with a high-frequency large-current switch bridge arm is optimized, and the wafer-level challenge is solved. According to the embodiments, the equalization work of each power unit of the wafer under the action of the high-frequency switch is realized, so that the wafer can work in high-frequency large-current operation. However, during actual use, the package leading-out impedance of each power electrode of the wafer, especially the alternating current impedance, still affects the current sharing effect in the wafer. Therefore, the package lead-out impedance also needs to be uniformly symmetrical.

It will be apparent to those skilled in the art that the present application is not limited to the details of the exemplary embodiments described above, and that the present application can be embodied in other specific forms without departing from the spirit or essential characteristics of the application. Therefore, regardless of which point the embodiments should be considered as exemplary and not restrictive, the scope of the application is defined by the appended claims rather than by the foregoing description, and therefore, it is intended that all changes which come within the meaning and range of equivalency of the claims are to be embraced within their scope. Any reference signs in the claims should not be regarded as limiting the involved claims.

In addition, it should be understood that although the description is described in terms of implementations, but not every implementation includes only one independent technical solution, the description is merely for clarity, a person skilled in the art should use the description as a whole, and the technical solutions in the embodiments may also be appropriately combined to form other embodiments that can be understood by a person skilled in the art.

What is claimed is:

1. A power semiconductor wafer of a single crystal wafer integrated high-frequency bridge arm, comprising: a substrate and a device structure area, wherein the device structure area is arranged on one surface of the substrate; the device structure area comprises a first switch area, a second switch area and a logic circuit area; the logic circuit area provides driving signals to the first switch and the second switch;
wherein the first switch area is used for arranging a first switch, the second switch area is used for arranging a second switch, and the first switch and the second switch are connected in series to form a high-frequency bridge arm; a DC+ electrode, a DC− electrode and an SW electrode are arranged on the power semiconductor wafer, the DC+ electrode and the DC− electrode are electrically connected with the two ends of the high-frequency bridge arm respectively, and the SW electrode is electrically connected with the midpoint end of the high-frequency bridge arm;
wherein the device structure area is provided with a long edge and a short edge, the length of the long edge is greater than the length of the short edge; at least one part of the first switch area is a first long-strip-shaped area parallel to the long edge, at least one part of the second switch area is a second long-strip-shaped area parallel to the long edge, and the first long-strip-shaped area and the second long-strip-shaped area are arranged side by side in the direction perpendicular to the long edge.

2. The power semiconductor wafer of claim 1, wherein the device structure area is a long-strip-shaped area, the device structure area only comprises a first long-strip-shaped area and a second long-strip-shaped area, and the first long-strip-shaped area and the second long-strip-shaped area are adjacent and are arranged in parallel.

3. The power semiconductor wafer of claim 2, wherein the logic circuit area is arranged in the area adjacent to the short edge or to the long edge of the power semiconductor area.

4. The power semiconductor wafer of claim 1, wherein at least one long edge is used for setting a decoupling capacitor, the decoupling capacitor is arranged along the long edge, the decoupling capacitor is arranged on the outer side of the device structure area, and the decoupling capacitor is connected with the high-frequency bridge arm in parallel.

5. The power semiconductor wafer of claim 1, wherein the second switch area surrounds at least three sides of the first switch area.

6. The power semiconductor wafer of claim 5, wherein the second switch area completely surrounds the first switch area.

7. The power semiconductor wafer of claim 6, wherein the logic circuit area is disposed at a central axis of the device structure area parallel to the long edge.

8. The power semiconductor wafer of claim 5, wherein the second switch area is C-shaped, the first switch area is a sleeping T shape, the second switch area partially surrounds the first switch area, and the first switch area and the second switch area are complementary.

9. The power semiconductor wafer of claim 5, wherein the first switch area and the second switch area are both C-shaped; the C-shaped at the inner side at least partially surrounds the logic circuit area; and the C-shaped at the outer side surround at the inner side s at least three sides of the C shape at the inner side.

10. The power semiconductor wafer of claim 9, wherein the logic circuit area is a sleeping T shape.

11. The power semiconductor wafer of claim 9, wherein the first switch area is C-shaped, the second switch area fully surrounds the first switch area, the first switch area and the second switch area are combined to form a C-shaped power area, and the C-shaped power area surrounds at least three sides of the logic circuit area.

12. The power semiconductor wafer of claim 9, wherein the first switch area is C-shaped; the second switch area partially surrounds the first switch area, and the first switch area and the second switch area are combined to form a C-shaped power area; a part of the left edge of the C-shaped power area is a first switch area; and the C-shaped power area surrounds at least three sides of the logic circuit area.

13. The power semiconductor wafer of claim 1, wherein the logic circuit area comprises a third long-strip-shaped area parallel to the long edge, and the third long-strip-shaped area is arranged at the central axis of the device structure area parallel to the long edge.

14. The power semiconductor wafer of claim 13, wherein the central axis penetrates through the logic circuit area.

15. The power semiconductor wafer of claim 13, wherein the first switch area and the second switch area form a power area, and the power area surrounds at least three sides of the logic circuit area.

16. The power semiconductor wafer of claim 15, wherein the power area surrounds all of the logic circuit areas.

17. The power semiconductor wafer of claim 13, wherein the logic circuit area divides the device structure area into a first switch area group and a second switch area group, and the first switch area group and the second switch area group are respectively arranged on two opposite sides of the logic circuit area; and the first switch area group and the second switch area group are symmetrical along a central axis; and a first switch area and a second switch area are respectively arranged in the first switch area group and in the second switch area group.

18. The power semiconductor wafer of claim 17, wherein the switch areas arranged on the two sides of the logic circuit area are long-strip-shaped, and the long sides of each long-strip-shaped are parallel to each other.

19. The power semiconductor wafer of claim 18, wherein the device structure area further comprises a driving area, and the driving area is a long-strip-shaped parallel to the long edge; and the driving area is arranged in the logic area, and every two adjacent of the first switching area and the second switching area.

20. The power semiconductor wafer of claim 18, wherein the switch areas arranged on the two sides of the logic circuit area are respectively provided with a long-strip-shaped switch area.

21. The power semiconductor wafer of claim 17, wherein the second switch area surrounds at least three sides of the first switch area.

22. The power semiconductor wafer of claim 21, wherein the second switch area completely surrounds the first switch area.

23. The power semiconductor wafer of claim 21, wherein the second switch area is C-shaped, and the first switch area is long-strip-shaped; the first switch area is adjacent to the logic circuit area at one long edge, and the first switch area is adjacent to the second switch area at the other long edge and the two short edges.

24. The power semiconductor wafer of claim 1, wherein the device structure area further comprises a driving area, and the driving area is a long strip parallel to the long edge; and each first switching area is adjacent to at least one driving area, and/or each second switching area is adjacent to at least one driving area.

25. The power semiconductor wafer of claim 1, wherein the power semiconductor wafer is characterized in that a bus layer is arranged above the device structure area, the bus layer comprises a DC+ bus wiring layer, a DC− bus wiring layer and an SW bus wiring layer, and the DC+ electrode, the DC− electrode and the SW electrode are electrically connected with the high-frequency bridge arm through the corresponding bus wiring layer.

26. The power semiconductor wafer of claim 25, wherein the SW bus wiring layer is disposed across the first switch area and the second switch area; the DC+ bus wiring layer is disposed on the first switch area and the DC− bus wiring layer is disposed on the second switch area, or the DC+ bus wiring layer is disposed on the second switch area, and the DC− bus wiring layer is disposed on the first switch area.

27. The power semiconductor wafer of claim 25, further comprising: a DC+ bus lead-out piece, a DC− bus lead-out piece, and an SW bus lead-out piece, wherein each wiring area is provided with at least one bus lead-out piece; the bus lead-out piece is electrically connected to the corresponding wiring area; the total cross-sectional area of the SW bus lead-out piece is greater than the total cross-sectional area of the DC+ bus lead-out piece.

28. The power semiconductor wafer of claim 25, wherein the device structure area comprises a first sub-area, and a second switch area in the first sub-area surrounds at least three sides of the first switch area; the first sub-area corresponds to a first bus layer, and a DC+ bus wiring layer in the first bus layer semi-surrounds the DC− bus wiring layer and the SW bus wiring layer.

29. The power semiconductor wafer of claim 25, wherein the device structure area comprises a second sub-area, the first switch area and the second switch area in the second sub-area are both long-strip-shaped, and the first switch area is arranged between the second switch areas; the second sub-area corresponds to the second bus layer, the SW bus wiring layer of the second bus layer spans the second switch area, and the length of the SW bus wiring layer in the longitudinal direction is greater than 50% of the length of the second sub-area in the longitudinal direction; and the DC+ bus wiring layer of the second bus layer is arranged between the DC− bus wiring layer.

30. The power semiconductor wafer of claim 29, wherein the DC+ electrodes in two adjacent second bus layers are electrically connected, and DC− electrodes in two adjacent second bus layers are electrically connected.

31. The power semiconductor wafer of claim 29, wherein the SW bus wiring layer comprises two extension sections, and the two extension sections are respectively arranged between the DC+ bus wiring layer and the two DC− bus wiring layers.

32. The power semiconductor wafer of claim 25, wherein the device structure area comprises a second sub-area, the first switch area and the second switch area in the second sub-area are both long-strip-shaped, and the first switch area is arranged between the second switch areas; the second sub-area corresponds to the second bus layer, and the second bus layer is arranged in the longitudinal direction according to the sequence of the DC− bus wiring layer, the SW bus wiring layer, the DC+ bus wiring layer, the SW bus wiring layer and the DC− bus wiring layer; and each DC− bus wiring layer, the SW bus wiring layer and the DC+ bus wiring layer are each provided with a bus lead-out piece.

33. The power semiconductor wafer of claim 25, wherein the device structure area comprises a second sub-area, the first switch area and the second switch area in the second sub-area are both long-strip-shaped, and the first switch area in the second sub-area is arranged between the second switch area and the logic circuit area; the second sub-area corresponds to the second bus layer, and the plane layout of the second bus layer is sequentially arranged in the longitudinal direction according to the sequence of the DC− bus wiring layer, the SW bus wiring layer and the DC+ bus wiring layer; and the DC− bus wiring layer, the SW bus wiring layer and the DC+ bus wiring layer are each provided with a bus lead-out piece.

34. The power semiconductor wafer of claim 33, wherein the DC− bus wiring layer, the SW bus wiring layer and the DC+ bus wiring layer are all long-strip-shaped; and the bus lead-out piece is aligned and arranged in the longitudinal column direction.

35. The power semiconductor wafer of claim 33, wherein the bus lead-out piece arranged on the SW bus wiring layer is staggered with the position of the bus lead-out piece arranged on the DC− bus wiring layer and the DC+ bus wiring layer; and the DC− bus wiring layer, the SW bus wiring layer and the DC+ bus wiring layer are respectively arranged to alternately change with wide and narrow along the transverse, and are wide at the position where the bus lead-out piece is arranged.

36. The power semiconductor wafer of claim 25, wherein the device structure area comprises a first sub-area and a second sub-area, and the first switch area and the second switch area in the first sub-area are in an enclosed layout; and the first switch area and the second switch area in the second sub-area are arranged in parallel; and the first sub-area is located at the end of the second sub-area; and the DC− bus wiring layer, the SW bus wiring layer and the DC+ bus wiring layer in the second sub-area are repeatedly formed by multiple repeating units side by side; the DC− bus wiring layer in the first sub-area is connected with the DC− bus wiring layer in the second sub-area; the SW bus wiring layer in the first sub-area is connected with the SW bus wiring layer in the second sub-area; and the DC+ bus wiring layer in the first sub-area is connected with the DC+ bus wiring layer in the second sub-area.

37. The power semiconductor wafer of claim 1, wherein the device structure area further comprises a built-in capacitor area;
the built-in capacitor area and the first switch area are adjacent in the long edge direction, and/or the built-in capacitor area and the second switch area are adjacent in the long edge direction;
the built-in capacitor area is used for setting a device area capacitor, and the device area capacitor and the high-frequency bridge arm are connected in parallel.

38. The power semiconductor wafer of claim 37, wherein the device structure area is arranged on a plane layout layer by layer from inside to outside according to the sequence of a built-in capacitor area, a first switch area and a second switch area.

39. The power semiconductor wafer of claim 37, wherein the device structure area is arranged on a plane layout layer by layer from inside to outside according to the sequence of the first switch area, the second switch area and the built-in capacitor area.

40. The power semiconductor wafer of claim 37, wherein at least two first switch areas and at least two second switch areas are arranged, and the device structure areas are sequentially arranged in the longitudinal direction according to the sequence of a second switch area, a first switch area, a built-in capacitor area, a first switch area and a second switch area on a plane layout.

41. The power semiconductor wafer of claim 37, wherein at least two second switch areas are arranged, the device structure areas are arranged on a plane layout layer by layer from inside to outside according to the sequence of a second switch area, a built-in capacitor area, a first switch area and a second switch area.

42. The power semiconductor wafer of claim 25, further comprising: a built-in layered capacitor, the built-in layered capacitor being formed by a dielectric layer embedded in the bus wiring layer, and the built-in layered capacitor and the high-frequency bridge arm being connected in parallel.

43. The power semiconductor wafer of claim 25, wherein the bus wiring layer further comprises a capacitor connection pad, and the capacitor connection pad is located at a corresponding position of the logic circuit area projected on the bus wiring layer.

44. The power semiconductor wafer of claim 43, wherein the capacitor connection pads are provided with a plurality of arrays arranged in an array.

45. The power semiconductor wafer of claim 17, wherein the logic circuit area provides two groups of driving signals with 180 degrees of staggered phases to the first switch area group and the second switch area group.

46. The power semiconductor wafer of claim 1, wherein the device structure area comprises a plurality of switch area groups with the same area, and each switch area group comprises at least one first switch area and at least one second switch area; and the logic circuit area is used for providing at least two groups of mutually staggered driving signals to the switch area group, and each group of driving signals respectively drives different switch area groups.

47. The power semiconductor wafer of claim 46, wherein the plurality of switch area groups are arranged along the central axis of the device structure area, and arranged the two sides of the central axis symmetrically.

48. The power semiconductor wafer of claim 46, wherein the first switch area and the second switch area in each switch area group are b long-strip-shaped.

49. The power semiconductor wafer of claim 47, wherein the plurality of switch area groups comprise first to fourth switch area groups, the first switch area group and the third switch area group are located on one side of the central axis of the device structure area, and the second switch area group and the fourth switch area group are located on the other side of the central axis of the device structure area; and the logic circuit area is used for providing four groups of driving signals with 90 degrees of staggered phases in sequence to the first to fourth switch area groups.

50. The power semiconductor wafer of claim 46, wherein the logic circuit area is located on the central axis of the device structure area, and arranged the two sides of the logic circuit area symmetrically.

51. A power conversion module, comprising: a bridge arm type circuit;
wherein the bridge arm type circuit comprises an outer decoupling capacitor and the power semiconductor wafer according to claim 1, wherein the outer decoupling capacitor array is arranged on the outer side of at least one long edge of the power semiconductor wafer, and the outer decoupling capacitor and the high-frequency bridge arm are connected in parallel.

52. The power conversion module of claim 51, wherein the bridge arm circuit further comprises a laminated decoupling capacitor; the laminated capacitor is stacked above the power semiconductor wafer and corresponds to the logic circuit area; the laminated decoupling capacitor and the high-frequency bridge arm are connected in parallel; and the laminated decoupling capacitor is a silicon capacitor.
